(19) United States
(12) Patent Application Publication
(10) Pub. No.: US 2012/0307578 A1
(43) Pub. Date: Dec. 6, 2012

(54) SEMICONDUCTOR DEVICE HAVING REDUNDANT SELECT LINE TO REPLACE REGULAR SELECT LINE

(75) Inventor: Hidekazu NOGUCHI, Tokyo (JP)

(73) Assignee: Elpida Memory, Inc., Tokyo (JP)

(21) Appl. No.: 13/488,265

(22) Filed: Jun. 4, 2012

(30) Foreign Application Priority Data
Jun. 6, 2011 (JP) 2011-126194

(51) Int. Cl. G11C 29/00

(52) U.S. Cl. 365/200

(57) ABSTRACT

Disclosed herein is a semiconductor device that includes a plurality of normal memory cells, a plurality of first normal lines each coupled to corresponding one or ones of the normal memory cells, a plurality of redundant memory cells, and first and second redundant lines each coupled to corresponding one or ones of the redundant memory cells. The first redundant line is configured to replace selected one or ones of the normal lines and the second line is configure to replace any one of the selected one or ones of the normal lines and remaining one or ones of the normal lines.

### BACKGROUND OF THE INVENTION

1. Field of the Invention

The present invention relates to a semiconductor device, and more particularly to a semiconductor device that includes redundant select lines for replacing defective select lines such as defective word lines.

2. Description of Related Art

A dynamic random access memory (DRAM) that is a typical semiconductor memory device includes an extremely large number of memory cells. A storage capacity of DRAM is 1 Gbits or more in recent years. It is difficult to make all memory cells operate properly, and some memory cells are found to be defective in the manufacturing phase. Defective memory cells are replaced with spear memory cells provided in the memory device in the manufacturing phase, whereby a memory device that can operate properly is shipped.

Memory cells are typically replaced in units of word lines or bit lines (see Japanese Patent Application Laid-Open No. H9-63295). For example, if a defective word line is found in a certain memory block, the defective word line is replaced with a redundant word line provided in the same memory block. However, this method has a disadvantage in that it is impossible to preplace all defective word lines with the redundant word lines if many defective word lines are found on a certain memory block. For that reason, a so-called flexible redundancy method has recently been employed which includes replacing defective word lines in one memory block with redundant word lines arranged in another memory block.

However, the so-called flexible redundancy method needs a large number of fuse elements for storing the addresses of defective word lines. There has thus been a problem that the fuse elements occupy a greater area on the chip.

### SUMMARY

In one embodiment, there is provided a semiconductor device that includes: a plurality of segments exclusively selected based on a first address group configured by a plurality of address bits, each of the segments including a plurality of word lines exclusively selected based on a second address group configured by at least one address bit different from the address bits configuring the first address group; a plurality of first redundant groups exclusively selected based on the second address group, each of the first redundant groups including a first redundant word line and a first fuse circuit that stores a respective first value, each of the first redundant word lines being selected when an associated one of the first redundant groups is selected based on the second address group and a value of the first address group is coincident with the first value stored in an associated one of the first fuse circuits; and a second redundant group including a second redundant word line and a second fuse circuit that stores a second value, the second redundant word line being selected when a value of the first and second the address groups is coincident with the second value.

In another embodiment, such a device is derived that includes a plurality of normal memory cells, a plurality of first normal lines each coupled to corresponding one or ones of the normal memory cells, a plurality of redundant memory cells, and first and second redundant lines each coupled to corresponding one or ones of the redundant memory cells, the first redundant line being configured to replace selected one or ones of the normal lines and the second line being configure to replace any one of the selected one or ones of the normal lines and remaining one or ones of the normal lines.

In still another embodiment, there is provided a devise that comprises: a normal memory cell array including a plurality of normal word lines and a plurality of normal memory cells each coupled to an associated one of the normal word lines, the normal word lines including a first group of normal word lines and a second group of normal word lines; a redundant memory cell array including a plurality of redundant word lines and a plurality of redundant memory cells each coupled to an associated one of the redundant word lines, the redundant word lines including a plurality of first redundant word lines and a plurality of second redundant word lines; and a redundant control circuit configured to restrict each of the first redundant word lines to replacing the first group of normal word lines and to assign each of the second redundant word lines for replacing both the first and second groups of normal word lines.

### BRIEF DESCRIPTION OF THE DRAWINGS

FIG. 1 is a block diagram of an entire semiconductor device 10 according to an embodiment of the present invention;

FIG. 2 is a schematic diagram for explaining the layout of the semiconductor device 10 shown in FIG. 1;

FIG. 3 is a schematic diagram for explaining the structure of one of banks shown in FIG. 2;

FIG. 4 is a schematic diagram showing the configuration of the memory blocks MB and RMB;

FIG. 5 is a schematic diagram for explaining the configuration of a memory block MB;

FIG. 6 is a schematic diagram for explaining the configuration of a memory block RMB;

FIG. 7 is a schematic diagram for explaining the structure of a segment SEG;

FIG. 8 is a schematic diagram for explaining the configuration of the redundant segments RSEG1 and RSEG2;

FIG. 9 is a circuit diagram of a hit signal generation circuit 40;

FIG. 10 is a circuit diagram of a hit signal generation circuit 50;

FIG. 11 is a circuit diagram of the fuse circuit F;

FIG. 12 is a circuit diagram of the comparison circuit C;

FIG. 13 is a timing chart for explaining the operation of the hit signal generation circuit 40 shown in FIG. 9;

FIG. 14 is a circuit diagram of a hit signal generation circuit 50a;

FIG. 15 is a circuit diagram of hit signal generation circuits 50b and 50c;

FIG. 16 is a circuit diagram of a hit signal generation circuit 50d;

FIG. 17 is a circuit diagram of hit signal generation circuit 40e;

FIG. 18 is a circuit diagram of hit signal generation circuit 50e;

FIG. 19 is a circuit diagram of a comparison circuit Ce according to a first example;

FIG. 20 is a circuit diagram of a comparison circuit Ce according to a second example;

FIG. 21 is a circuit diagram of a hit signal generation circuit 40f;

FIG. 22 is a circuit diagram of a decoder DEC4A;

FIG. 23 is a circuit diagram of a decoder DEC8A;

FIG. 24 is a circuit diagram of the multiplexer MUX4A;

FIG. 25 is a circuit diagram of the multiplexer MUX8A;

FIG. 26 is a circuit diagram of a dynamic multiplexer MUX4A;

FIG. 27 is a circuit diagram of a hit signal generation circuit 50f;

FIG. 28 is a circuit diagram of a decoder DEC8A;

FIG. 29 is a circuit diagram of the multiplexer MUX2A;

FIGS. 30A to 30F are schematic diagrams showing several relationships between redundant segments RSEG1 and RSEG2;

FIG. 31 is a schematic diagram for explaining an example of replacement in a bank where memory blocks RMB have the structure shown in FIG. 30F;

FIG. 32 is a schematic diagram for explaining the structure of a memory bank according to another example; and

FIGS. 33A to 33D are schematic diagrams for explaining the structure of memory block RMB (1) to RMB(4), respectively.

### DETAILED DESCRIPTION OF THE EMBODIMENTS

A representative example of the technical concept of the present invention for solving the problem will be described below. It will be understood that what the present invention claims are not limited to such a technical concept but set forth in the claim section. A technical concept of the present invention is to reduce the number of needed fuse elements by limiting the ranges of defective word lines some redundant word lines can replace and improve the relief efficiency by not limiting the ranges of defective word lines other redundant word lines can replace. This can reduce the number of fuse elements and perform efficient replacement even when the locations of occurrence of defective word lines are somewhat unevenly distributed.

Preferred embodiments of the present invention will be explained below in detail with reference to the accompanying drawings.

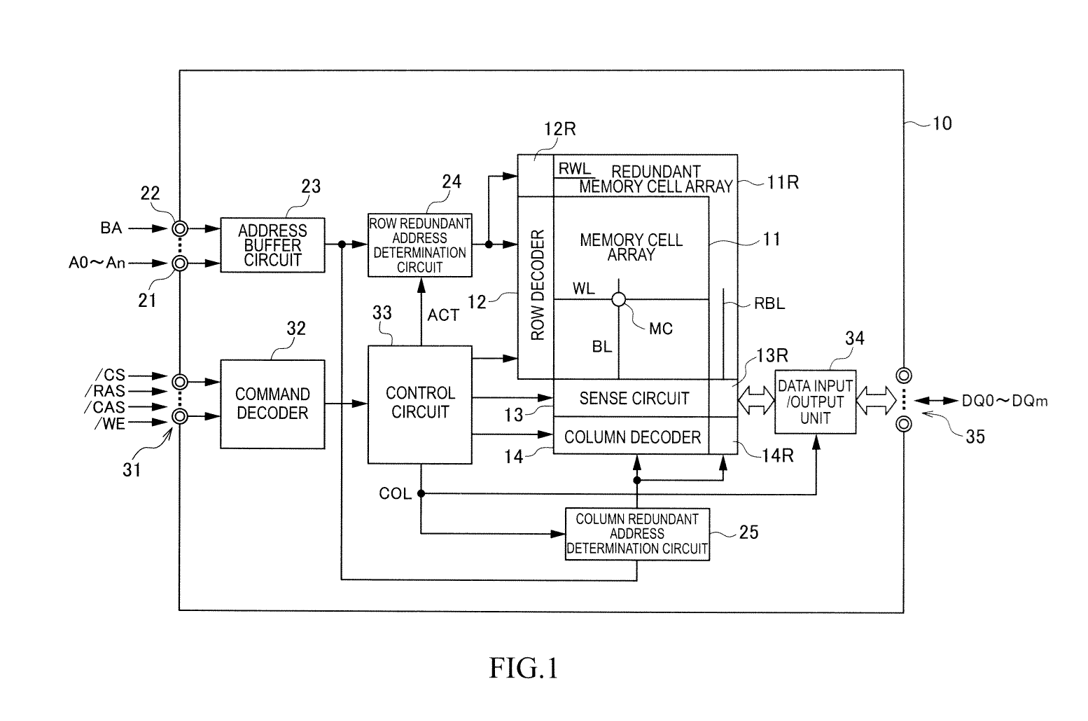

Referring now to FIG. 1, the semiconductor device 10 according to the present embodiment is a DRAM includes a memory cell array 11. The memory cell array 11 includes a plurality of word lines WL, a plurality of bit lines BL, and a plurality of memory cells MC arranged at the intersections of the word lines WL and the bit lines BL. Note that FIG. 1 shows only one word line WL, one bit line BL, and one memory cell MC. The memory cell MC has a first volatile memory element having a first structure.

The word lines WL are selected by a row decoder 12. An address signal A0 to An is supplied to the row decoder 12 through an address terminal 21, an address buffer circuit 23, and a row redundant address determination circuit 24. The row redundant address determination circuit 24 takes in the address signal A0 to An supplied from the address buffer circuit 23 and controls the row decoder 12 and a redundant row decoder 12R when an active signal ACT supplied from a control circuit 33 is activated. The active signal ACT is a signal that is activated when a command decoder 32 determines that command signals supplied from outside through command terminals 31 show a predetermined combination (active command). The command signals supplied to the command terminals 31 include a chip select signal /CS, a row address strobe signal /RAS, a column address strobe signal /CAS, and a write enable signal /WE.

As shown in FIG. 1, the semiconductor device 10 further includes a redundant memory cell array 11R. The redundant memory cell array 11R includes redundant word lines RWL and redundant bit lines RBL. The redundant word lines RWL are selected by a redundant row decoder 12R. The redundant row decoder 12R is activated by the row redundant address determination circuit 24 when a row address to be accessed is a row address corresponding to a defective word line. In such a manner, a defective word line is replaced with a redundant word line RWL.

The bit lines BL included in the memory cell array 11 are connected to sense amplifiers that are included in a sense circuit 13. The sense amplifiers are selected by a column decoder 14. The address signal A0 to An is supplied to the column decoder 14 through the address terminal 21, the address buffer circuit 23, and a column redundant address determination circuit 25. The column redundant address determination circuit 25 takes in the address signal A0 to An supplied from the address buffer circuit 23 and controls the column decoder 14 and a redundant column decoder 14R when a column signal CCL supplied from the control circuit 33 is activated.

As shown in FIG. 1, there are provided a redundant sense circuit 13R and the redundant column decoder 14R corresponding to the redundant memory cell array 11R. The redundant bit lines RBL and redundant sense amplifiers connected thereto are selected by the redundant column decoder 14R. The redundant column decoder 14R is activated by the column redundant address determination circuit 25 when a column address to be accessed is a column address corresponding to a defective bit line. In such a manner, a defective bit line is replaced with a redundant bit line RBL.

Sense amplifiers or redundant sense amplifiers selected by the column decoder 14 or the redundant column decoder 14R are connected to data input/output terminals 35 through a data input/output unit 34. When the command signals indicate a read operation, read data DQ0 to DQm read from memory cells MC designated by the address signal A0 to An are output from the data input/output terminals 35 to outside. When the command signals indicate a write operation, write data DQ0 to DQm supplied from outside to the data input/output terminals 35 are written to memory cells MC that are designated by the address signal A0 to An.

In fact, the memory cell array 11 and the redundant memory cell array 11R are divided into a plurality of banks. Which bank to select is specified by a bank address BA which is supplied through an address terminal 22.

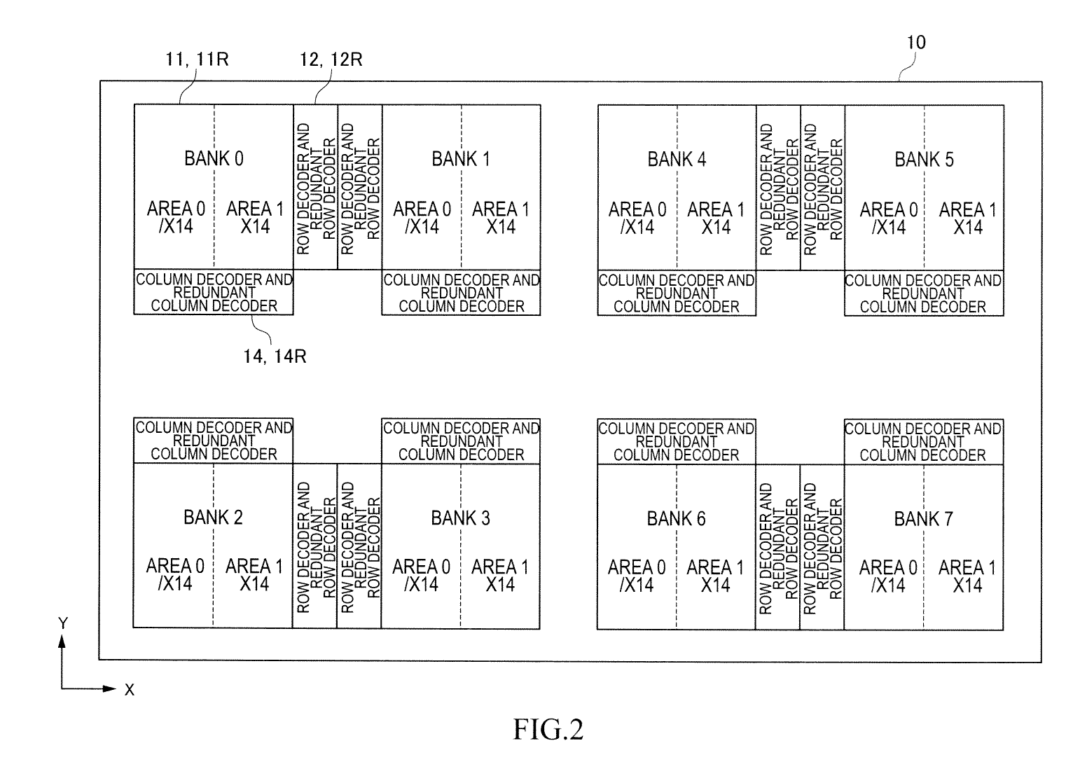

Turning to FIG. 2, in the semiconductor device 10 according to the present invention, the memory cell array 11 and the redundant memory cell array 11R are divided into eight banks including bank 0 to bank 7. A row decoder 12 and a redundant row decoder 12R corresponding to each bank are arranged on an X-direction side of the bank. A column decoder 14 and a redundant column decoder 14R corresponding to each bank are arranged on a Y-direction side of the bank. In the present example, an address signal A0 to An consists of 15 bits A0 to A14. The most significant address bit A14 selects area 0 or area 1. The most significant address bit A14 is supplied during row access. In this specification and drawings, the most significant address bit A14 will be denoted by “X14.” Similarly, address bits A0 to A13 supplied during row access will be denoted by “X0” to “X13.”

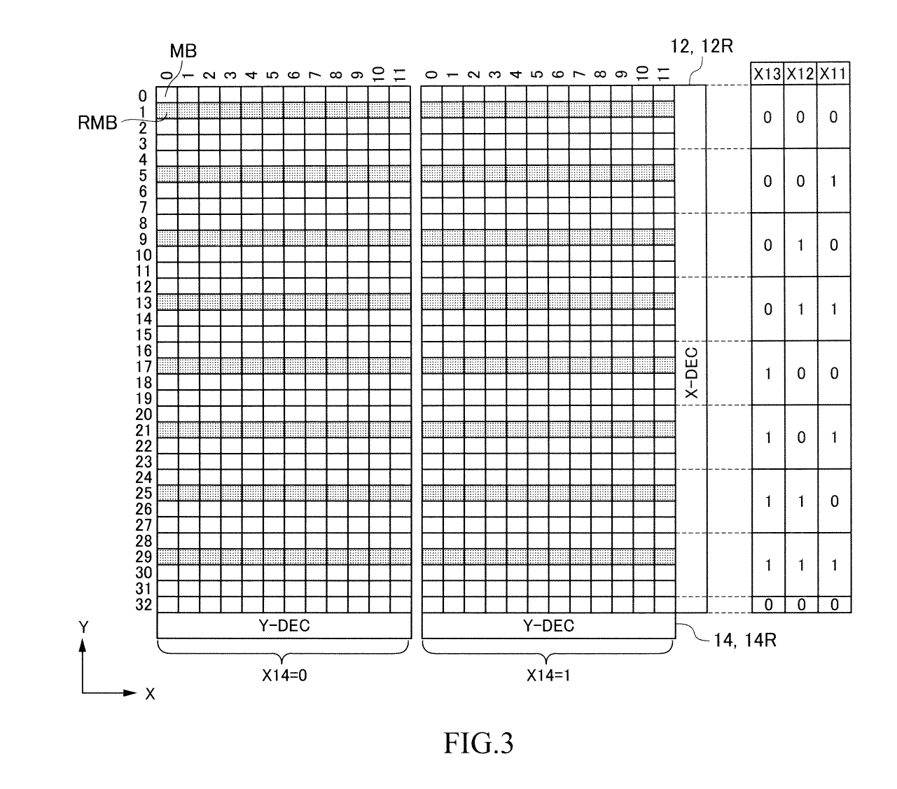

Turning to FIG. 3, in the semiconductor device 10 according to the present embodiment, a single bank is divided into 24 memory blocks in the X direction and 33 memory blocks in the Y direction. The left half, i.e., 12 memory blocks of the 24 memory blocks divided in the X direction are selected when the most significant address bit X14 has a value of 0. The right half, 12 memory blocks are selected when the most significant address bit X14 has a value of 1. Which memory block to select from the 12 selected memory blocks is specified by a column address.

Which memory block to select from the 33 memory blocks divided in the Y direction is specified by the address bits X13 to X9 of a row address. Both memory blocks MB0 and MB32 lying at the ends in the Y direction have a storage capacity one half that of the other memory blocks. The two memory blocks MB0 and MB32 together are equivalent to one of the other memory blocks. The reason is that the semiconductor device 10 according to the present embodiment uses a so-called open bit line system.

In the present embodiment, the 33 memory blocks divided in the Y direction constitute groups each including four blocks. Which group to select from the resulting eight groups is specified by the address bits X13 to X11 of a row address. For example, when all the address bits X13 to X11 have a value of 0 as shown in FIG. 3, the group including the memory blocks MB0 to MB3 is selected. It should be noted that the group including the memory blocks MB0 to MB3 also includes the memory block MB32. The reason is as described above.

Four memory blocks constituting each group include three normal memory blocks MB that include no redundant word line. The remaining one is a memory block RMB that includes redundant word lines. In FIG. 3, memory blocks RMB that include redundant word lines are shown hatched. The example shown in FIG. 3 deals with the case where the second memory block from the top in four memory blocks constituting each group is a memory block RMB including redundant word lines. However, the present invention is not limited thereto.

Whereas a detailed description will be given later, each of the hatched memory blocks in the present embodiment includes 16 redundant word lines RWL. In the 16 redundant word lines RWL, eight redundant word lines RWL can only replace defective word lines within a limited range. The other eight redundant word lines RWL can replace defective word lines in an unlimited range. Suppose that access to a defective word line is not stopped even during a replacement operation according to the specification. In such a case, the replacement of a defective word line with a redundant word line RWL that is arranged in the same memory block RMB or a memory block RMB adjoining in the Y direction is disabled (replacement disable condition). The reason is that if access to a defective word line is not stopped even during a replacement operation, replacing the defective word line with a redundant word line RWL arranged in the same memory block RMB or a memory block RMB adjoining in the Y direction can lead to the simultaneous activation of two word lines in one memory block or two memory blocks that share sense amplifiers. Such simultaneous activation causes data corruption. On the other hand, if access to a defective word line is stopped during a replacement operation according to the specification, the foregoing limitation is irrelevant.

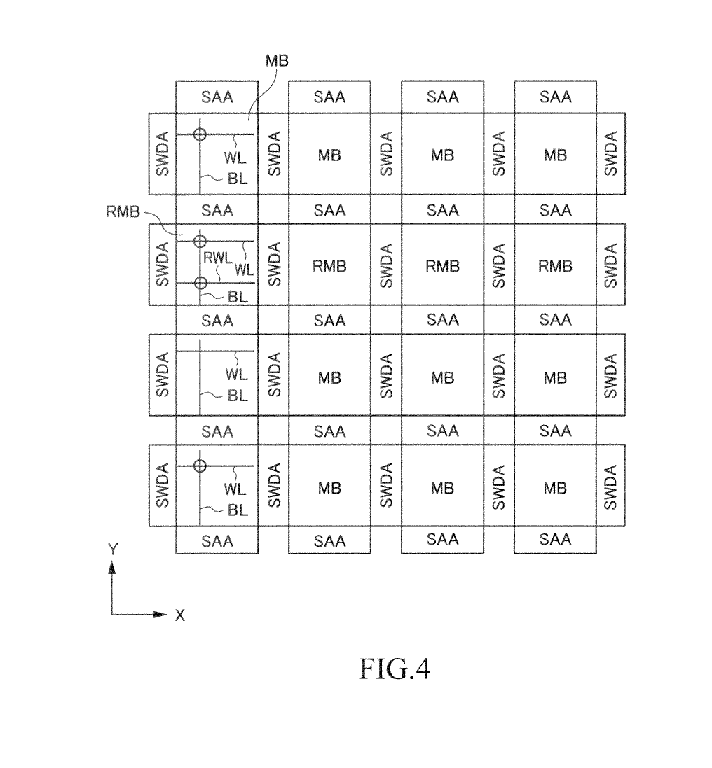

Turning to FIG. 4, memory blocks MB and RMB are laid out in a matrix in the X direction and Y direction. Sub word driver arrays SWDA are arranged between memory blocks adjoining in the X direction. Sense amplifier arrays SAA are arranged between memory blocks adjoining in the Y direction. The sub word driver arrays SWDA are circuit blocks each including a plurality of sub word drivers. Each sub word driver drives a corresponding word line WL. The sense amplifier arrays SAA are circuit blocks each including a plurality of sense amplifiers. Each sense amplifier amplifies a potential difference between a bit line BL that is arranged in either one of memory blocks MB adjoining in the Y direction and a bit line BL that is arranged in the other of the memory blocks MB adjoining in the Y direction. The memory blocks RMB also include redundant word lines RWL. Redundant bit lines are omitted in FIG. 4.

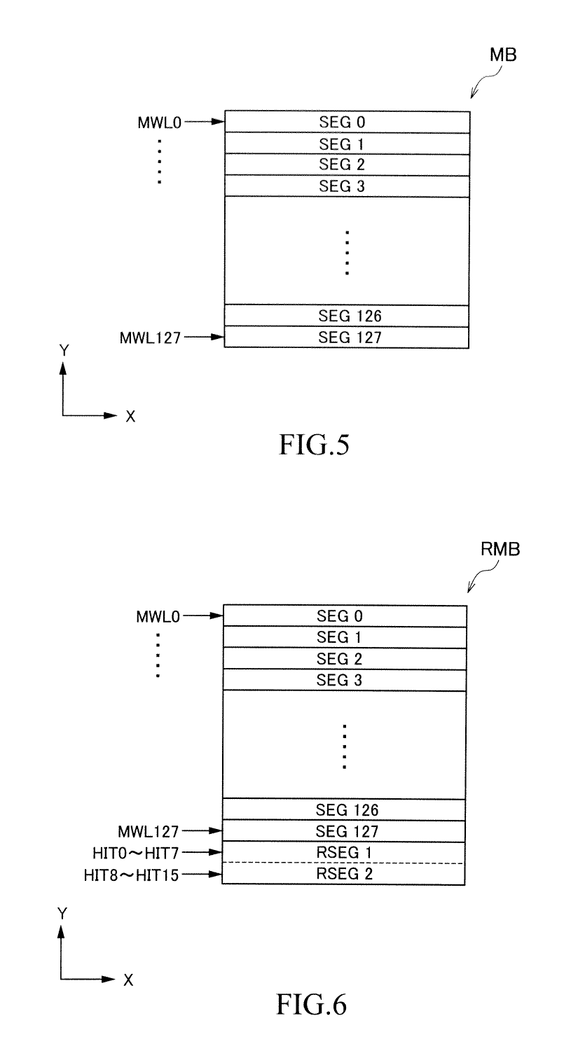

Turning to FIG. 5, a memory block MB including no redundant word line is divided into 128 segments which are arranged in the Y direction. The segments SEG0 to SEG127 are exclusively selected by the address bits X8 to X2 of a row address. Specifically, the row decoder 12 decodes the address bits X8 to X2 of a row address, and activates any one of 128 main word lines MWL0 to MWL127 corresponding to the segments SEG0 to SEG127, respectively. The segment whose corresponding main word line MWL is activated is the segment to be accessed. A word line WL is selected by the remaining address bits X1 and X0 of the row address.

Turning to FIG. 6, a memory block RMB including redundant word lines have redundant segments RSEG1 and RSEG2 in addition to the same configuration as that of the memory block MB shown in FIG. 5. The redundant segment RSEG1 is a segment including redundant word lines RWL that can replace defective word lines within a limited range. The redundant segment RSEG2 is a segment including redundant word lines RWL that can replace defective word lines in an unlimited range. As will be described later, the redundant segment RSEG1 is selected by hit signals HIT0 to HIT7. The redundant segment RSEG2 is selected by hit signals HIT8 to HIT15.

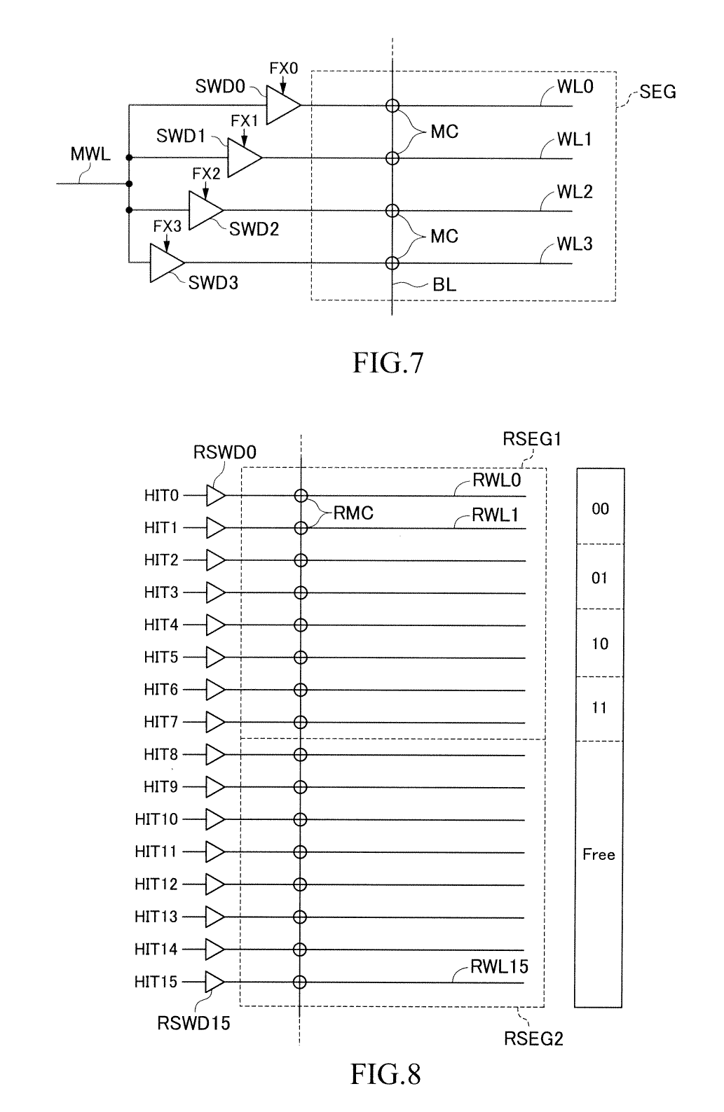

Turning to FIG. 7, a segment SEG includes four word lines WL0 to WL3. Memory cells MC are arranged at the intersections of the word lines WL0 to WL3 and bit lines BL. The word lines WL0 to WL3 are driven by respective corresponding sub word drivers SWD0 to SWD3. The sub word drivers SWD0 to SWD3 drive the corresponding word lines WL0 to WL3 to a selection level when the main word line MWL assigned to the segment is activated and respective corresponding sub word drive signals FX0 to FX3 are activated. The sub word drive signals FX0 to FX3 are exclusively selected by the address bits X1 and X0 of a row address. The word lines WL0 to WL3 may sometimes be referred to as sub word lines.

Turning to FIG. 8, a redundant segment RSEG1 includes eight redundant word lines RWL0 to RWL7. A redundant segment RSEG2 includes eight redundant word lines RWL8 to RWL15. Redundant memory cells RMC are arranged at the intersections of the redundant word lines RWL0 to RWL15 and bit lines BL. The redundant memory cell RMC has the first volatile memory element having the first structure. The redundant word lines RWL0 to RWL15 are driven by respective corresponding redundant sub word drivers RSWD0 to RSWD15. The redundant word lines RWL0 to RWL15 may sometimes be referred to as redundant sub word lines. The sub word drive signals FX0 to FX3 supplied to the sub word drivers SWD0 to SWD3 are also supplied to the redundant word lines RWL0 to RWL15. Redundant sub word drive signals FXJ0 to FXJ3 (not shown) dedicated to redundancy purposes may be supplied instead of the sub word drive signals FX0 to FX3. In the former case, the foregoing replacement disable condition is applied if access (activation) to a defective word line is not stopped.

The two redundant word lines RWL0 and RWL1 are provided in order to replace word lines WL that can be selected by the sub word drive signal FX0. In FIG. 8, the redundant word lines RWL0 and RWL1 are expressed as “00.” The two redundant word lines RWL2 and RWL3 are provided in order to replace word lines WL that can be selected by the sub word drive signal FX1. In FIG. 8, the redundant word lines RWL2 and RWL3 are expressed as “01.” The two redundant word lines RWL4 and RWL5 are provided in order to replace word lines WL that can be selected by the sub word drive signal FX2. In FIG. 8, the redundant word lines RWL4 and RWL5 are expressed as “10.” The two redundant word lines RWL6 and RWL7 are provided in order to replace word lines WL that can be selected by the sub word drive signal FX3. In FIG. 8, the redundant word lines RWL6 and RWL7 are expressed as “11.” If the sub word drive signals FX0 to FX3 are shared by the sub word lines and redundant sub word lines, logic for giving priority to the hit signals HIT0 to HIT15 is added to the row redundant address determination circuit 24. This precludes restrictions occurring from the connection of the sub word drive signals FX0 to FX3. Now, the eight redundant word lines RWL8 to RWL15 are provided in order to replace arbitrary word lines WL. In FIG. 8, the redundant word lines RWL8 and RWL15 are expressed as “Free.” “Free” means that the redundant word lines RWL8 and RWL15 may be arbitrarily used as any of “00,” “01,” “10,” and “11” (i.e., not fixed in advance). All the redundant word lines RWL may be used regardless of which segment a defective word line WL to be replaced belongs to. According to the foregoing replacement disable condition, if access to a defective word line is not stopped even during a replacement operation, the replacement of a defective word line with a redundant word line RWL that is arranged in the same memory block RMB or a memory block RMB adjoining in the Y direction is disabled. For example, the redundant word line RWL0 is used for replacement in the context of a first ROM circuit that stores first predetermined information indicated by a first address group. The redundant word line RWL2 is used for replacement in the context of a third ROM circuit that stores third predetermined information indicated by the first address group. The redundant word line RWL8 is used for replacement in the context of a second ROM circuit that stores second predetermined information indicated by the first address group and a second address group. The first address group and the second address group will be defined later.

The redundant sub word drivers RSWD0 to RSWD15 are activated by the respective corresponding hit signals HIT0 to HIT15. The hit signals HIT0 to HIT15 are generated by the row redundant address determination circuit 24 shown in FIG. 1.

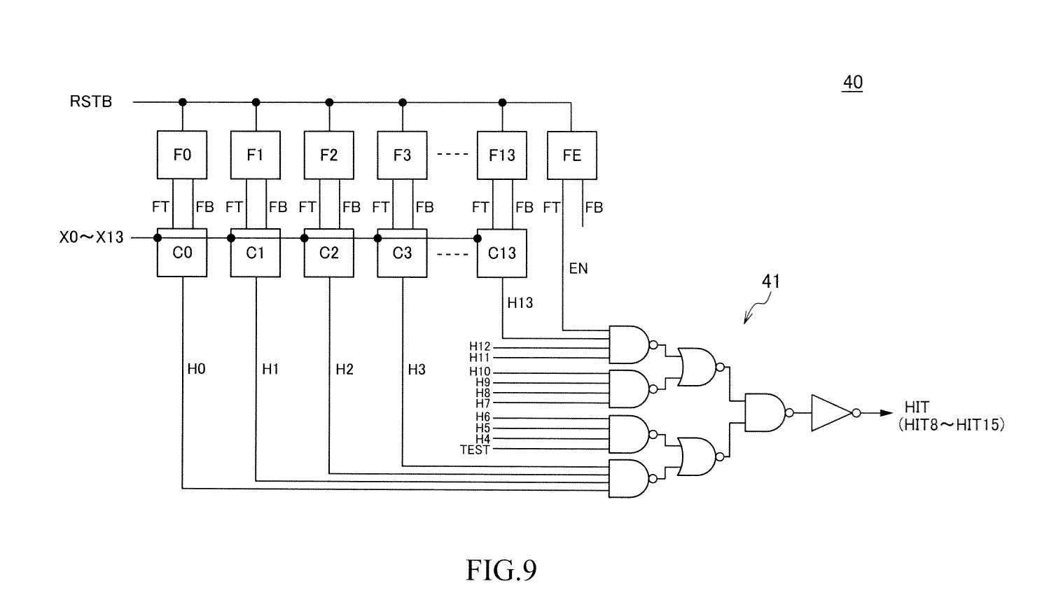

Turning to FIG. 9, a hit signal generation circuit 40 generates any one of the hit signals HIT8 to HIT15 corresponding to the redundant segment RSEG2. The hit signal generation circuit 40 may sometimes be referred to as a “second ROM circuit.”

Each of the redundant word lines RWL8 to RWL15 constituting a redundant segment RSEG2 is provided with a hit signal generation circuit 40. A redundant segment RSEG2 thus includes eight hit signal generation circuits 40. A hit signal generation circuit 40 and its corresponding redundant word line RWL may sometimes be referred to as a “second redundant group.”

As shown in FIG. 9, a hit signal generation circuit 40 includes fuse circuits F0 to F13 and an enable fuse circuit FE. The fuse circuits F0 to F13 correspond to the address bits X0 to X13 of a defective word line WL to be replaced, respectively. The fuse circuits F0 to F13 include fuse elements that store respective corresponding logical values in a nonvolatile manner. The fuse circuits F0 to F13 included in the hit signal generation circuit 40 may sometimes be referred to as “second fuse circuits.”

The upper address bits X2 to X13 among the address bits X0 to X13 may sometimes be referred to as a “first address group,” and the lower address bits X0 and X1 as a “second address group.” The hit signal generation circuit 40 thus stores both the first and second address groups (second predetermined information indicated by the first and second address groups). The fuse elements are not limited to any particular type. Optical fuse elements that can be cut by laser beam irradiation may be used. Electrical fuse elements that can be connected by causing a dielectric breakdown of a gate insulator by the application of a high voltage may be used. The enable fuse circuit FE is a circuit that indicates whether the hit signal generation circuit 40 is in a used state or unused state. The fuse circuits F0 to F13 and the enable fuse circuit FE perform a read operation on their fuse elements in response to a reset signal RSTB supplied from outside the semiconductor device 10, and hold the read logical values. The circuit configuration of the fuse circuits will be described later.

The logical values stored in the fuse circuits F0 to F13 are each output in the form of complementary signals FT and FB, and supplied to respective corresponding comparison circuits C0 to C13. The signals FT are positive outputs. The signals FB are negative outputs. A programmed fused circuit outputs a positive signal FT=high level and a negative signal FB=low level. On the other hand, an unprogrammed fuse circuit outputs a positive signal FT=low level and a negative signal FB=high level. As employed herein, a “programmed fuse element” refers to one that has been cut by laser beam irradiation in the case of an optical fuse element. In the case of an electrical fuse element, a “programmed fuse element” refers to one that has been dielectrically broken by the application of a high voltage.

The comparison circuits C0 to C13 are circuits that compare access-requested address bits X0 to X13 with the outputs of the fuse circuits F0 to F13, respectively. If the pieces of information coincide, the comparison circuits C0 to C13 activate coincidence signals H0 to H13 to a high level. The coincidence signals H0 to H13 are supplied to a hit determination circuit 41. Meanwhile, a positive output EN of the enable fuse circuit FE is simply supplied to the hit determination circuit 41. As a result, the hit determination circuit 41 activates its corresponding hit signal HIT (HIT8 to HIT15) to a high level if the enable fuse circuit FE is in a programmed state and all the access-requested address bits X0 to X13 coincide with the outputs of the fuse circuits F0 to F13. Note that a test signal TEST, which is supplied to the hit determination circuit 41, is always at a high level during normal operations.

In such a manner, a hit signal generation circuit 40 for controlling a redundant segment RSEG2 activates a corresponding hit signal HIT8 to HIT15 on condition that all the access-request address bits X0 to X13 coincide with the address bits X0 to X13 of a defective word line WL to be replaced. This means that the defective word line WL to be replaced is an arbitrary one.

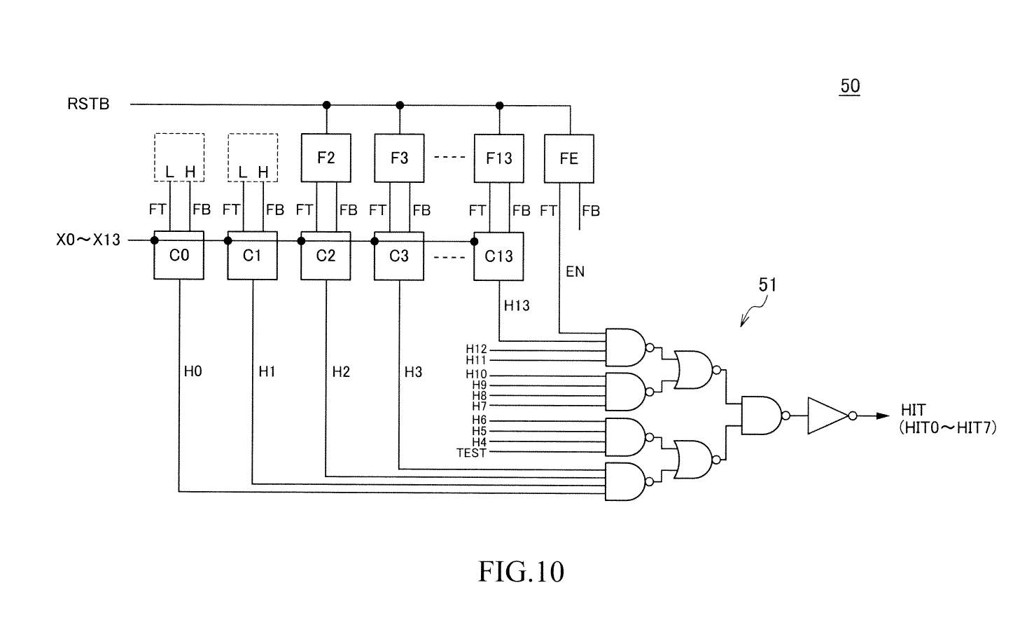

Turning to FIG. 10, a circuit diagram of a hit signal generation circuit 50 generates any one of the hit signals HIT0 to HIT7 corresponding to the redundant segment RSEG1. The hit signal generation circuit 50 may sometimes be referred to as a “first ROM circuit.”

Each of the redundant word lines RWL0 to RWL7 constituting a redundant segment RSEG1 is provided with a hit signal generation circuit 50. A redundant segment RSEG1 thus includes eight hit signal generation circuits 50. A hit signal generation circuit 50 and its corresponding redundant word line RWL may sometimes be referred to as a “first redundant group.”

As shown in FIG. 10, a hit signal generation circuit 50 includes fuse circuits F2 to F13 and an enable fuse circuit FE. The fuse circuits F2 to F13 correspond to the address bits X2 to X13 of a defective word line WL to be replaced, respectively. The fuse circuits F2 to F13 included in a hit signal generation circuit 50 may sometimes be referred to as “first fuse circuits.” Unlike the hit signal generation circuit 40, the hit signal generation circuit 50 does not include the fuse circuits F0 and F1 corresponding to the address bits X0 and X1 of a defective word line WL to be replaced. Consequently, the number of fuse circuits needed for a hit signal generation circuit 50 is two less than that for a hit signal generation circuit 40. A hit signal generation circuit 50 thus stores only a first address group (first predetermined information indicated by a first address group).

The comparison circuits C2 to C13 are circuits that compare the access-requested address bits X2 to X13 with the outputs of the fuse circuits F2 to F13, respectively. The comparison circuits C2 to C13 thereby compare the pieces of information. On the other hand, the comparison circuits C0 and C1 compare the access-requested address bits X0 and X1 with predetermined logical values, respectively. The comparison circuits C0 to C13 output coincidence signals H0 to H13, which are supplied to a hit determination circuit 51. In the example shown in FIG. 10, both the positive signals FT supplied to the comparison circuits C0 and C1 are fixed to a low level. As a result, a coincidence is detected when both the access-requested address bits X0 and X1 are at a low level. This means that the hit signal generation circuit 50 shown in FIG. 10 is one corresponding to redundant word lines RWL0 and RWL1 which are expressed as “00” in FIG. 8. In other words, such a hit signal generation circuit 50 is used to replace defective word lines WL that can be selected by the sub word drive signal FX0.

In a hit signal generation circuit 50 that corresponds to redundant word lines RWL2 and RWL3 expressed as “01” in FIG. 8, the positive signal FT supplied to the comparison circuit C0 is fixed to a high level and the positive signal FT supplied to the comparison circuit C1 is fixed to a low level. As a result, a coincidence is detected when the access-requested address bits X0 and X1 have a value of “01.” Such a hit signal generation circuit 50 is used to replace defective word lines WL that can be selected by the sub word drive signal FX1.

In a hit signal generation circuit 50 that corresponds to redundant word lines RWL4 and RWL5 expressed as “10” in FIG. 8, the positive signal FT supplied to the comparison circuit C0 is fixed to a low level and the positive signal FT supplied to the comparison circuit C1 is fixed to a high level. As a result, a coincidence is detected when the access-requested address bits X0 and X1 have a value of “10.” Such a hit signal generation circuit 50 is used to replace defective word lines WL that can be selected by the sub word drive signal FX2.

In a hit signal generation circuit 50 that corresponds to redundant word lines RWL6 and RWL7 expressed as “11” in

FIG. 8, both the positive signals FT supplied to the comparison circuits C0 and C1 are fixed to a high level. As a result, a coincidence is detected when the access-requested address bits X0 and X1 have a value of “11.” Such a hit signal generation circuit 50 is used to replace defective word lines WL that can be selected by the sub word drive signal FX3.

The positive signals FT and negative signals FB supplied to the comparison circuits C0 and C1 are fixed by connecting the lines directly to one of a power supply potential and a ground potential. The logic levels are not reprogrammable, whereas the no use of fuse elements makes the area occupied by the circuits for generating the signals extremely small as compared to with fuse elements.

As described above, a hit signal generation circuit 50 for controlling a redundant segment RSEG1 activates a corresponding hit signal HIT0 to HIT7 on condition that the address bits X0 and X1 to be accessed coincide with predetermined values and the address bits X2 to X13 to be accessed coincide with the address bits X2 to X13 of a defective word line WL to be replaced. This means that the range of defective word lines WL to be replaced is limited.

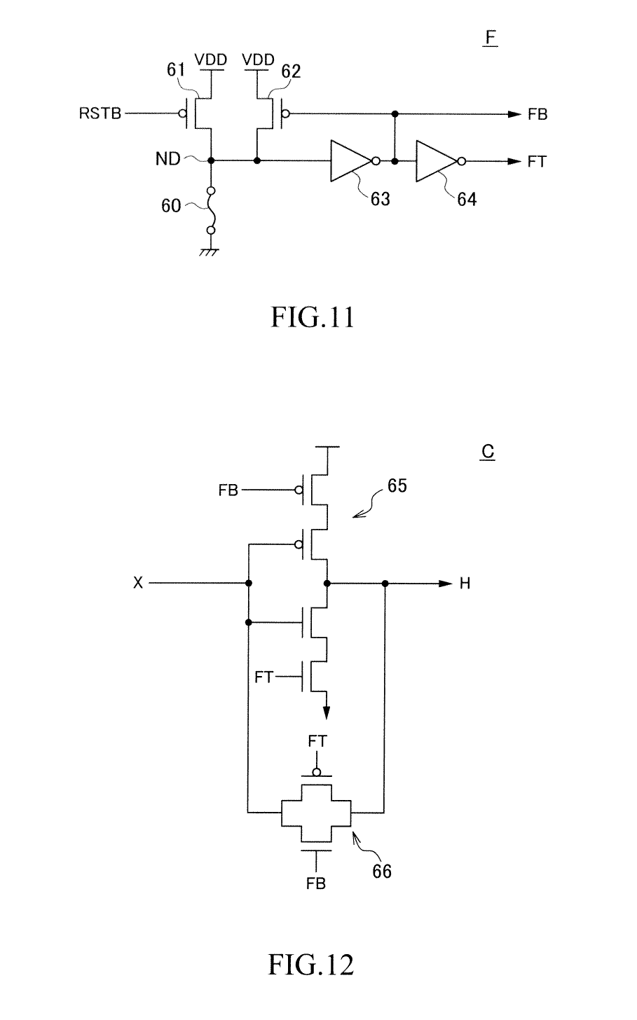

Turning to FIG. 11, there is a circuit diagram of the fuse circuit F. Since the fuse circuits F0 to F13 and FE have the same circuit configuration, the fuse circuits F0 to F13 and FE will be referred to simply as “fuse circuits F” if no particular distinction is needed.

As shown in FIG. 11, a fuse circuit F includes a fuse element 60 which is grounded at an end, and a fuse determination circuit that reads information stored in the fuse element 60. The fuse determination circuit includes P-channel MOS transistors 61 and 62 which are connected in parallel between a power supply potential VDD and the other end of the fuse element 60. The reset signal RSTB is supplied to the gate electrode of the transistor 61. When the reset signal RSTB is activated to a low level, the power supply potential VDD is applied to the connection node ND between the fuse element 60 and the transistors 61 and 62. The level of the connection node ND is output through inverters 63 and 64 as a positive signal FT, and through the inverter 63 as a negative signal FB. The negative signal FB is fed back to the gate electrode of the transistor 62. Consequently, when the reset signal RSTB is deactivated to a high level, the logic level read from the fuse element 60 is retained.

The reset signal RSTB is a kind of command signal supplied from outside the semiconductor device 10. The reset signal RSTB is temporarily set to a low level immediately after power-on, and then maintained at a high level. When the reset signal RSTB is set to a low level immediately after power-on, the connection node ND is connected to the power supply potential VDD through the transistor 61. If the fuse element 60 is conducting, the potential of the connection node ND will not increase beyond a threshold of the inverter 63. The positive signal FT thus becomes a low level, and the negative signal FB a high level. As employed herein, that a fuse element 60 is conducting refers to that the fuse element 60 is unprogrammed if the fuse element 60 is an optical fuse, and that the fuse element 60 is programmed if the fuse element 60 is an electrical fuse. Since the negative signal FB is fed back to the gate electrode of the transistor 62, the transistor 62 turns off. Consequently, when the reset signal RSTB is changed to a high level, the level of the connection node ND is fixed to the ground level.

On the other hand, if the fuse element 60 is non-conducting, the potential of the connection node ND increases beyond the threshold of the inverter 63 when the transistor 61 is turned on by the reset signal RSTB. The positive signal FT becomes a high level, and the negative signal FB a low level. As employed herein, that a fuse element 60 is non-conducting refers to that the fuse element 60 is programmed if the fuse element 60 is an optical fuse, and that the fuse element 60 is unprogrammed if the fuse element 60 is an electrical fuse. Since the negative signal FE is fed back to the gate electrode of the transistor 62, the transistor 62 turns on. Consequently, when the reset signal RSTB is changed to a high level, the level of the connection node ND is fixed to the power supply potential level.

Turning to FIG. 12, there is a circuit diagram of the comparison circuit C. Since the comparison circuits C0 to C13 have the same circuit configuration, the comparison circuits C0 to C13 will be referred to simply as “comparison circuits C” if no particular distinction is needed.

As shown in FIG. 12, a comparison circuit C includes a clocked inverter 65 and a transfer gate 66 which are connected in parallel. A corresponding address bit X is used as an input signal. The clocked inverter 65 is activated when the positive signal FT is at a high level and the negative signal FB is at a low level. On the other hand, the transfer gate 66 is activated when the positive signal FT is at a low level and the negative signal FB is at a high level. Consequently, if the corresponding address bit X coincides with the logic level of the positive signal FT, the corresponding coincidence signal H is activated to a high level. If the two do not coincide, the corresponding coincidence signal H is deactivated to a low level.

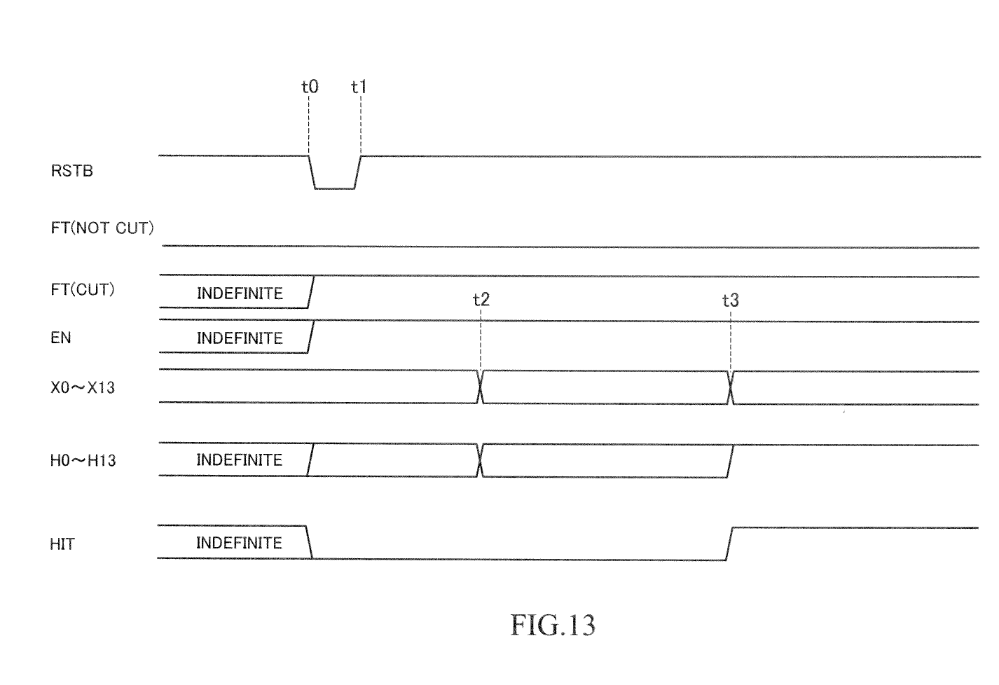

The operation of the hit signal generation circuit 40 shown in FIG. 9 will be explained with reference to FIG. 13.

As shown in FIG. 13, before time t0 immediately after power-on, the reset signal RSTB is still at a high level and the positive signals FT output from the fuse circuits F have indefinite values. In the period between times t0 and t1, the reset signal RSTB is activated to a low level and a read from the fuse elements 60 is performed. As a result, positive signals FT become a low level if fuse elements 60 are conducting (in the case of optical fuses, not cut). Positive signals FT become a high level if fuse elements 60 are non-conducting (in the case of optical fuses, cut). When the hit signal generation circuit 40 is in a used state, the output EN of the enable fuse circuit FE is also at a high level.

Subsequently, at times t2 and t3, an address signal is supplied from outside along with an active command. The comparison circuits C0 to C13 perform a comparison and determine the logic levels of the coincidence signals H0 to H13 according to the comparison results. In the example shown in FIG. 13, the address signal X0 to X13 input at time t2 does not coincide with the logic levels of the fuse circuits F0 to F13. The hit signal HIT thus remains at the low level. In contrast, the address signal X0 to X13 input at time t3 coincides with all the logic levels of the fuse circuits F0 to F13, whereby the hit signal HIT is activated to a high level. In such a manner, a comparison operation is performed each time an active command and an address signal are supplied.

The hit signal generation circuit 50 shown in FIG. 10 makes basically the same operation as that of the hit signal generation circuit 40.

With the configuration described above, when an address signal supplied along with an active command coincides with all the values retained in the fuse circuits F0 to F13, any one of the hit signals HIT0 to HIT15 is activated by the hit signal generation circuit 40 or 50. This selects any one of the redundant word lines RWL0 to RWL15 instead of the defective word line. All the fuse circuits F0 to F13 of the hit signal generation circuit 40 are programmable, which allows replacement of an arbitrary word line WL. On the other hand, in the hit signal generation circuit 50, only the fuse circuits F2 to F13 are programmable and the outputs corresponding to the fuse circuits F0 and F1 are fixed. Replaceable word lines WL are therefore limited. Concrete descriptions have been given in conjunction with FIGS. 7 and 8. The sub word drive signals FX0 to FX3 of defective word lines to be replaced with the redundant word lines RWL0 to RWL7 corresponding to the respective hit signal generation circuits 50 are thus fixed.

According to such a configuration, the number of fuse circuits needed for a hit signal generation circuit 50 is two less than the number of fuse circuits needed for a hit signal generation circuit 40. This can reduce the occupied area on the chip. Since the hit signal generation circuits 40 can replace any word lines, it is possible to replace all defective word lines with redundant word lines even if the defective word lines are somewhat unevenly distributed.

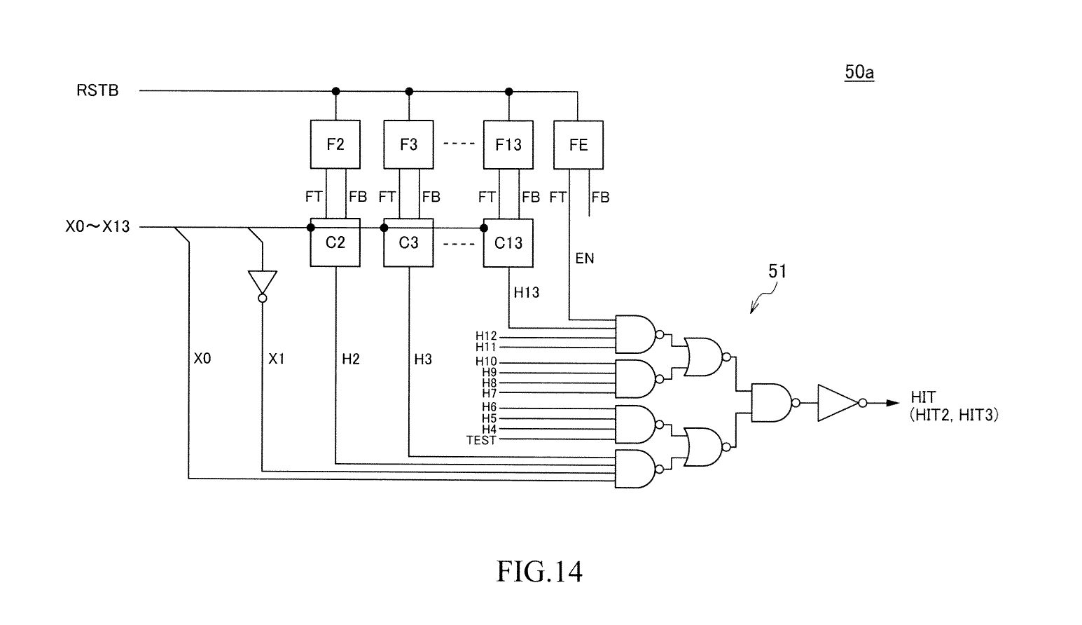

Turning to FIG. 14, there is a circuit diagram of a hit signal generation circuit 50a according to a modification. As an example, FIG. 14 shows a hit signal generation circuit 50a that corresponds to the redundant word lines RWL2 and RWL3 expressed as “01” in FIG. 8.

In the hit signal generation circuit 50a shown in FIG. 14, the comparison circuits C0 and C1 are deleted. The address bit X0 and an inverted signal of the address bit X1 are directly supplied to the hit determination circuit 51. Since the hit determination circuit 51 is activated when the address bit X0 is at high level and the address bit X1 is at a low level, the hit signal generation circuit 50a can perform the same operation as that of the hit signal generation circuit 50 shown in FIG. 10. Since the comparison circuits C0 and C1 are not needed, the occupied area on the chip can be reduced further.

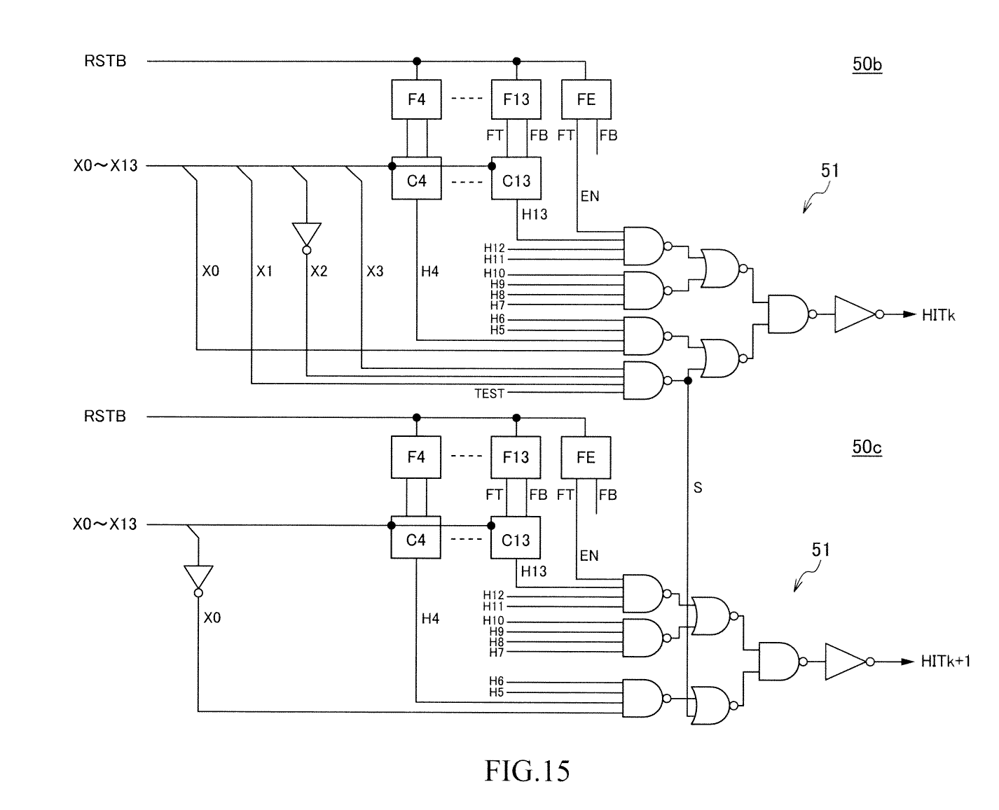

Turning to FIG. 15, there is a circuit diagram of hit signal generation circuits 50b and 50c according to another modification.

In the hit signal generation circuits 50b and 50c shown in FIG. 15, the lower four bits of the address signal are fixed. The fuse circuits corresponding to the address bits X0 to X3 are therefore deleted. The address bits X0, X1, and X3 are directly input to the hit determination circuit 51 that is included in the hit signal generation circuit 50b. An inverted signal of the address bit X2 is also input to the hit determination circuit 51. As a result, the hit determination circuit 51 is activated when the lower four bits X3 to X0 of the address signal are “1011.”

In the hit signal generation circuit 50c, an inverted signal of the address bit X0 is input to the hit determination circuit 51. The address bits X1 to X3 are not input directly to the hit determination circuit 51. Instead, an intermediate signal S generated by the hit signal generation circuit 50b is input to the hit determination circuit 51. The intermediate signal S is a signal obtained by ANDing the address bit X1, the inverted signal of the address bit X2, the address bit X3, and the test signal TEST. The test signal TEST is fixed to a high level during normal operations. As a result, the hit determination circuit 51 of the hit signal generation circuit 50c is activated when the lower four bits X3 to X0 of the address signal are “1010.” The use of the intermediate signal S eliminates the need for a gate circuit that logically synthesizes the address bits X1 to X3. This allows a further reduction in circuit scale.

To implement such a configuration, it is effective to juxtapose two hit signal generation circuits in which fixed address bits have close values. An example of the case where fixed address bits have close values is when the fixed address bits have a different value in only one bit. In the example shown in FIG. 15, the hit signal generation circuit 50b and the hit signal generation circuit 50c differ only in the address bit X0. Such hit signal generation circuits can be juxtaposed to reduce the length of wiring for transmitting the intermediate signal S.

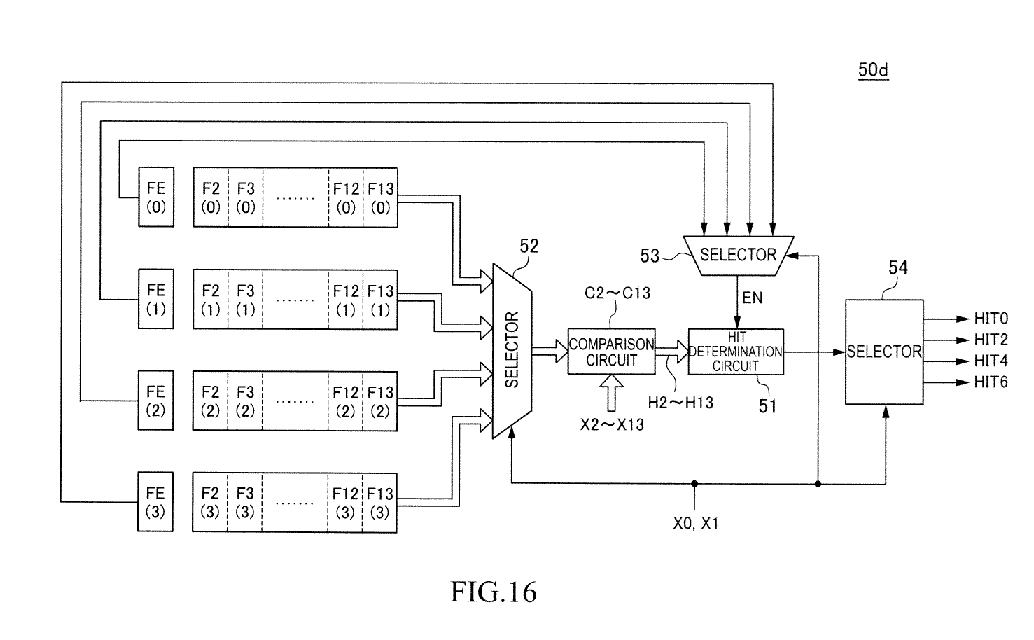

Turning to FIG. 16, there is a circuit diagram of a hit signal generation circuit 50d according to still another modification.

The hit signal generation circuit 50d shown in FIG. 16 includes four groups of fuse circuits F2(0) to F13(0), F2(1) to F13(1), F2(to F13(2), and F2(3) to F13(3). The fuse circuits F2(0) to F13(0) are used to store the address of a defective word line WL that can be selected by the sub word drive signal FX0. The fuse circuits F2(1) to F13(1) are used to store the address of a defective word line WL that can be selected by the sub word drive signal FX1. The fuse circuits F2(2) to F13(2) are used to store the address of a defective word line WL that can be selected by the sub word drive signal FX2. The fuse circuits F2(3) to F13(3) are used to store the address of a defective word line WL that can be selected by the sub word drive signal FX3.

The outputs of the fuse circuits are supplied to a selector 52. Any one of the groups of fuse circuits is selected by the address bits X0 and X1. Specifically, if the address bits X1 and X0 have a value of “00,” the outputs of the fuse circuits F2(0) to F13(0) are selected. If the address bits X1 and X0 have a value of “01,” the outputs of the fuse circuits F2(1) to F13(1) are selected. If the address bits X1 and X0 have a value of “10,” the outputs of the fuse circuits F2(2) to F13(2) are selected. If ₜhe address bits X0 and X1 have a value of “11,” the outputs of the fuse circuits F2(3) to F13(3) are selected.

The comparison circuits C2 to C13 compare the outputs of the fuse circuits selected by the selector 52 with the address bits X2 to X13, respectively. Coincidence signals H2 to H13 which show the comparison results are supplied to the hit determination circuit 51. An enable bit EN to be input to the hit determination circuit 51 is selected by a selector 53. The selector 53 is a circuit for selecting any one of enable fuse circuits FE(0) to FE(3) based on the address bits X1 and X0. The selection is the same as with the selector 52. If the enable bit EN and the coincidence signals H2 to H13 are all activated to a high level, a hit signal HIT is activated. The hit signal HIT is supplied to a selector 54. The selector 54 activates any one of hit signals HIT0, HIT2, HIT4, and HIT6 based on the address bits X1 and X0.

As described above, in the hit signal generation circuit 50d, the four groups of fuse circuits share the comparison circuits C2 to C13 and the hit determination circuit 51. This allows a further reduction in circuit scale. Such shared use is possible because the four groups of fuse circuits are exclusively used based on the address bits X0 and X1.

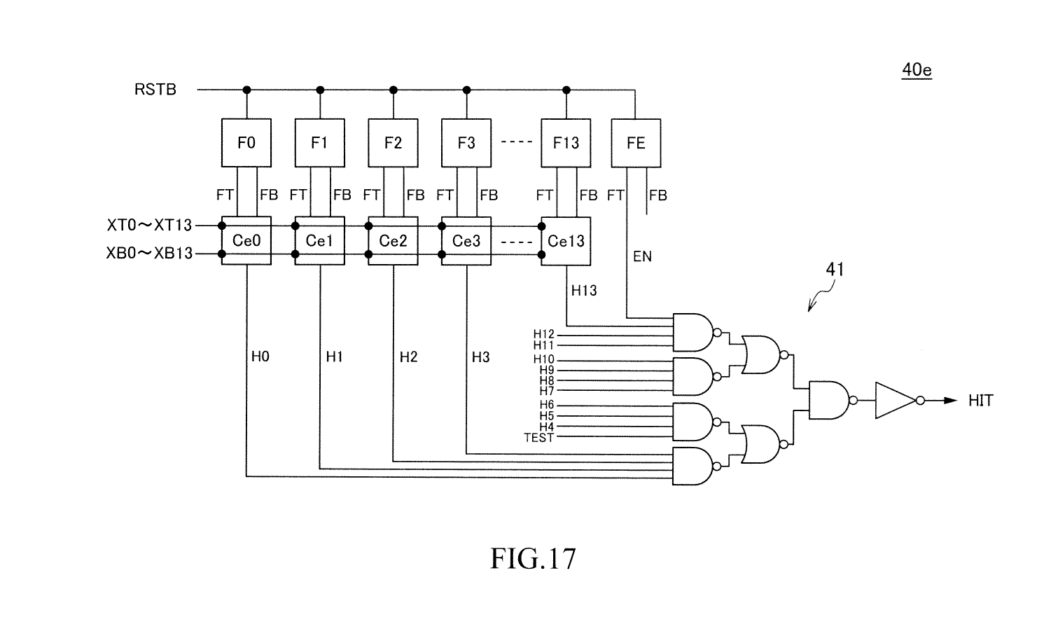

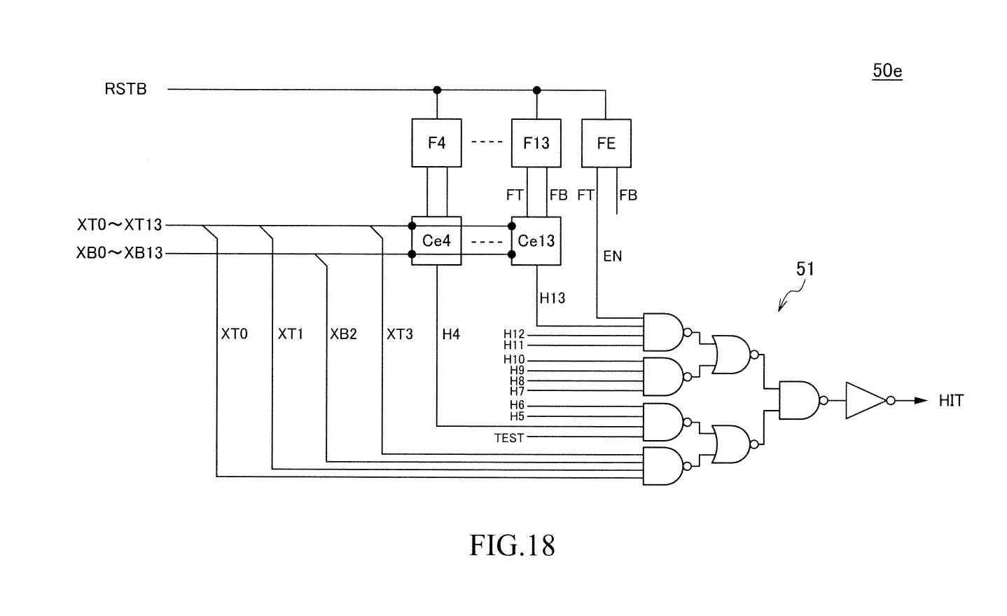

Turning to FIGS. 17 and 18, there are circuit diagrams of hit signal generation circuits 40e and 50e according to yet another modification.

The hit signal generation circuit 40e shown in FIG. 17 and the hit signal generation circuit 50e shown in FIG. 18 both use complementary address bits XT0 to XT13 and XB0 to XB13. In the hit signal generation circuit 40e, all the address bits XT0 to XT13 and XB0 to XB13 are supplied to comparison circuits Ce0 to Ce13, respectively. In the hit signal generation circuit 50e, the address bits XT4 to XT13 and XB4 to XB13 are supplied to comparison circuits Ce4 to Ce13, respectively. In the hit signal generation circuit 50e, some of the remaining address bits XT0 to XT3 and XB0 to XB3 are directly input to the hit determination circuit 51 in a predetermined combination. The reason is that the lower four bits of the address signal are fixed. Fuse circuits corresponding to such address bits XT0 to XT3 and XB0 to XB3 are thus deleted. Hereinafter, the comparison circuits Ce0 to Ce13 will be referred to simply as “comparison circuits Ce” when no particular distinction is needed.

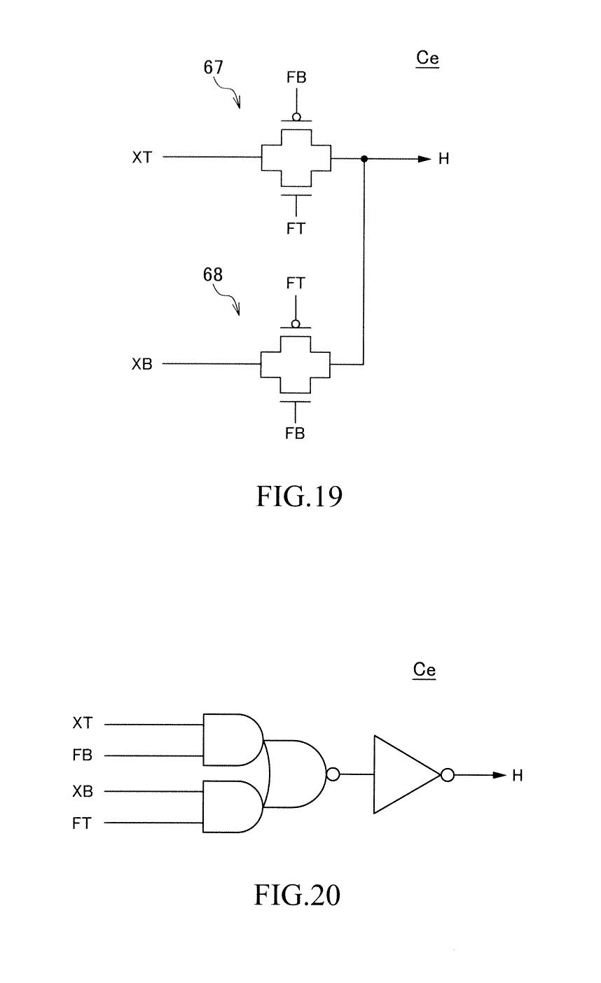

FIG. 19 shows a circuit diagram of a comparison circuit Ce according to a first example. The comparison circuit Ce shown in FIG. 19 includes a transfer gate 67 for passing the positive signal XT of an address bit and a transfer gate 68 for passing the negative signal XB of the address bit. The output signals of the transfer gates 67 and 68 are connected by a wired OR. The transfer gate 67 becomes conducting when the positive signal FT of a corresponding fuse circuit F is at a high level. On the other hand, the transfer gate 68 becomes conducting when the positive signal FT of the corresponding fuse circuit F is at a low level. Consequently, the comparison circuits Ce activate their corresponding coincidence signals H0 to H13 to a high level if the corresponding address bits X0 to X13 coincide with the outputs of the fuse circuits F0 to F13, respectively.

FIG. 20 shows a circuit diagram of a comparison circuit Ce according to a second example. The comparative circuit Ce shown in FIG. 20 is a complex gate circuit which ORs the AND output of the positive signal XT of an address bit and the negative signal FB of a fuse circuit F and the AND output of the negative signal XB of the address bit and the positive signal FT of the fuse circuit F. The comparison circuit Ce thereby performs the same operation as that of the comparison circuit Ce shown in FIG. 19.

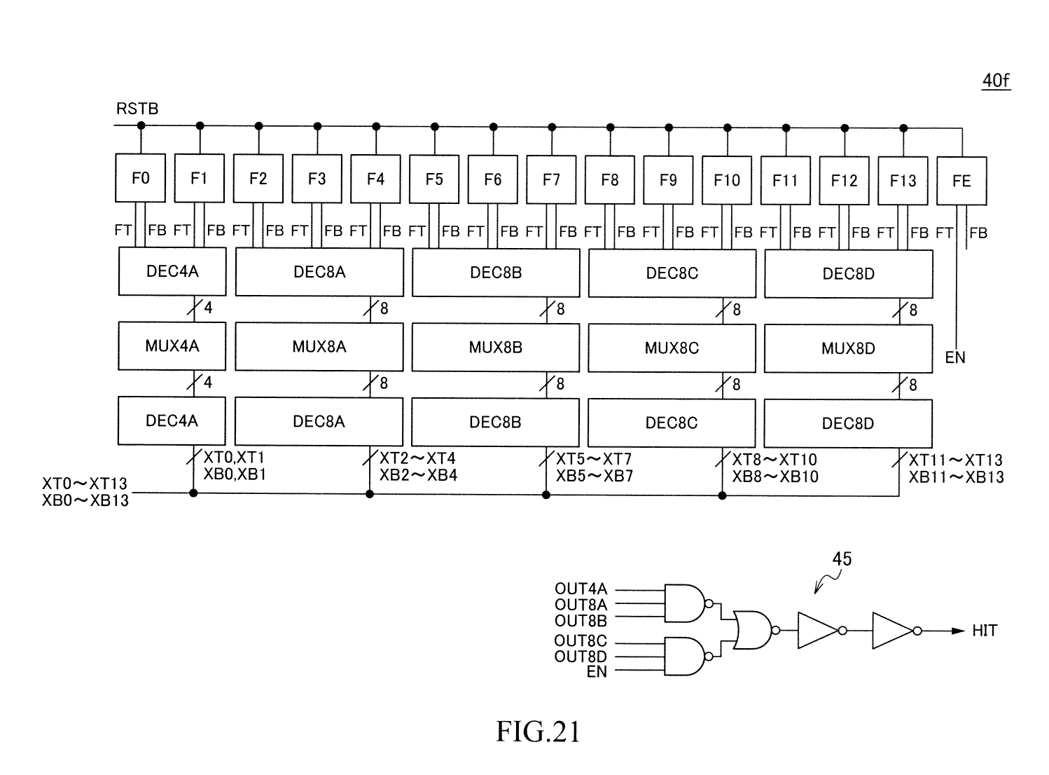

Turning to FIG. 21, the hit signal generation circuit 40f pre-decodes the complementary address bits XT0 to XT13 and XB0 to XB13 and the complementary outputs FT and FB of the fuse circuits F0 to F13, and compares the generated pre-decoded signals to generate a hit signal HIT.

Specifically, a decoder DEC4A decodes the outputs of the fuse circuits F0 and F1. A decoder DEC8A decodes the outputs of the fuse circuits F2 to F4. A decoder DEC8B decodes the outputs of the fuse circuits F5 to F7. A decoder DEC8C decodes the outputs of the fuse circuits F8 to F10. A decoder DEC8D decodes the outputs of the fuse circuits F11 to F13. The corresponding address bits X0 to X13 are also decoded by decoders DEC4A, DEC8A, DEC8B, DEC8C, and DEC8D of the same configurations. The outputs (4-bit or 8-bit) of the decoders each include only one activated bit.

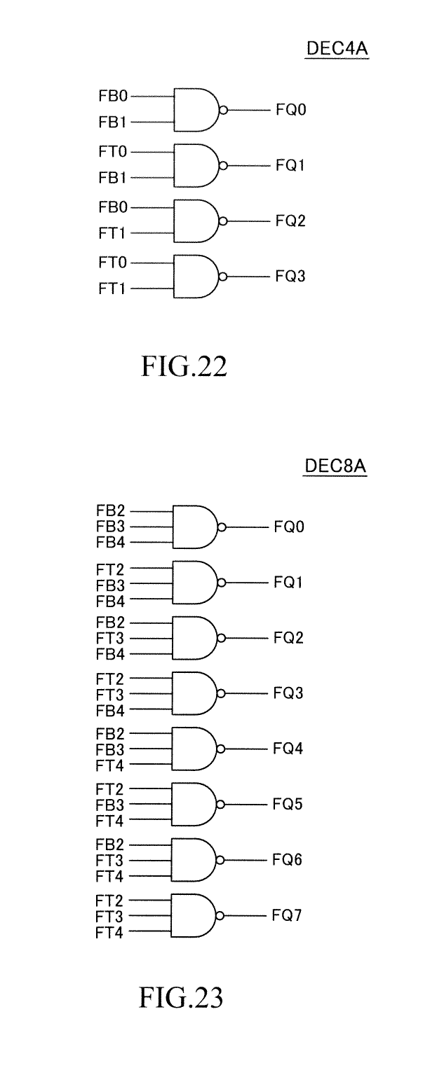

Turning to FIG. 22, a decoder DEC4A shown in FIG. 21 includes four two-input NAND gate circuits. As shown in FIG. 23, a decoder DEC8A shown in FIG. 21 includes eight three-input NAND gate circuits. Different combinations of complementary signals are input to the four two-input NAND gate circuits constituting the decoder DEC4A, respectively. Similarly, different combinations of complementary signals are input to the eight three-input NAND gate circuits constituting the decoder DEC8A, respectively. In FIG. 22, the outputs FT0, FT1, FB0, and FB1 of the fuse circuits F0 and F1 are used as the complementary signals. In FIG. 23, the outputs FT2 to FT4 and FB2 to FB4 of the fuse circuits F2 to F4 are used as the complementary signals. The other decoders DEC8B, DEC8C, and DEC8D have the same circuit configuration as that of the decoder DEC8A shown in FIG. 23. As shown in FIG. 21, the outputs of the decoders DEC4A, DEC8A, DEC8B, DEC8C, and DEC8D are supplied to multiplexers MUX4A, MUX8A, MUX8B, MUX8C, and MUX8D, respectively.

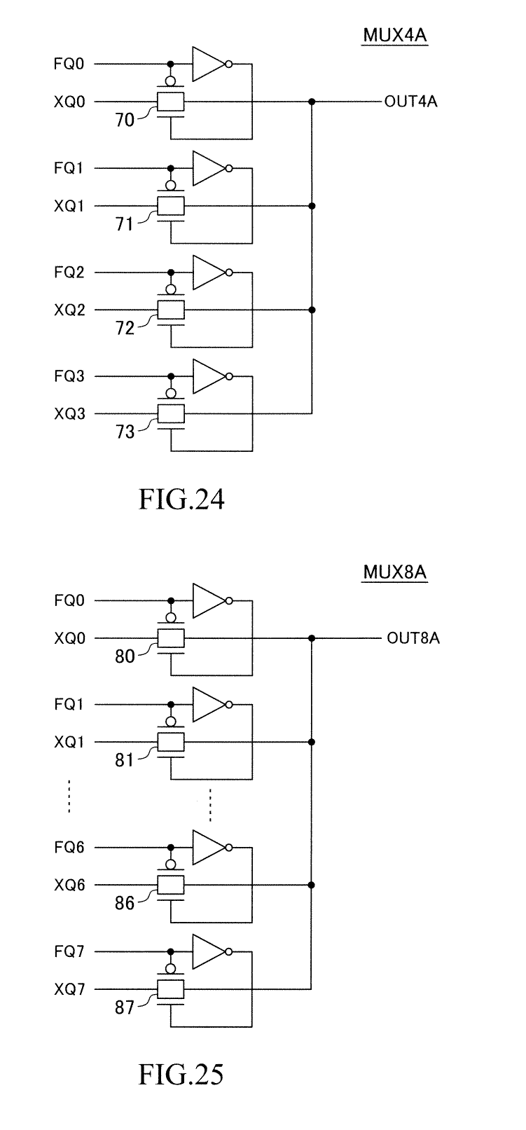

Turning to FIG. 24, the multiplexer MUX4A shown in FIG. 21 includes four transfer gates 70 to 73. Decoding signals XQ0 to XQ3 generated by decoding the address bits X0 and X1 are supplied to the transfer gates 70 to 73, respectively. The transfer gates 70 to 73 are exclusively made conducting by decoding signals FQ0 to FQ3 that are generated by decoding the outputs of the fuse circuits F0 and F1. The output nodes of the transfer gates 70 to 73 are connected by a wired OR and supplied to the hit determination circuit 45 shown in FIG. 21 as a coincidence signal OUT4A.

Turning to FIG. 25, the multiplexer MUX8A shown in FIG. 21 includes eight transfer gates 80 to 87. Decoding signals XQ0 to XQ7 generated by decoding the address bits X2 to X4 are supplied to the transfer gates 80 to 87, respectively. The transfer gates 80 to 87 are exclusively made conducting by decoding signals FQ0 to FQ7 that are generated by decoding the outputs of the fuse circuits F2 to F4. The output nodes of the transfer gates 80 to 87 are connected by a wired OR and supplied to the hit determination circuit 45 shown in FIG. 21 as a coincidence signal OUT8A. The other multiplexers MUX8B, MUX8C, and MUX8D also have the circuit configuration shown in FIG. 25.

With such configurations, the hit signal HIT is activated when all the outputs of the five multiplexers MUX4A, MUX8A, MUX8B, MUX8C, and MUX8D are at a high level and the enable signal EN is at a high level.

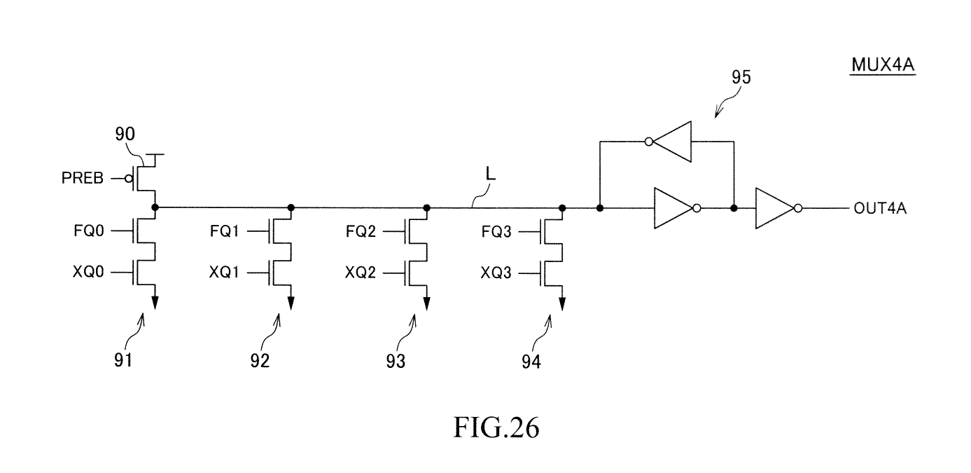

Turning to FIG. 26, the dynamic multiplexer MUX4A shown in FIG. 21 includes a P-channel MOS transistor 90 and series transistors 91 to 94. The P-channel MOS transistor 90 precharges a line L in response to a precharge signal PREB. The series transistors 91 to 94 discharge the line L. The series transistors 91 to 94 each include two N-channel MOS transistors. The decoding signals XQ0 to XQ3 generated by decoding the address bits X0 and X1 are supplied to the gate electrodes of either ones of the N-channel MOS transistors. The decoding signal FQ0 to FQ3 generated by decoding the outputs of the fuse circuits F0 and F1 are supplied to the gate electrodes of the other N-channel MOS transistors.

If at least either one of two transistors constituting each of the series transistors 91 to 94 is off, the line L maintains a precharged state and the coincidence signal OUT4A becomes a high level. On the other hand, if any one of the series transistors 91 to 94 includes two transistors that are on, the line L is discharged and the coincidence signal OUT4A becomes a low level. The logic level of the coincidence signal OUT4A is retained by a flip-flop 95 until the precharge signal PREB is activated again.

The other multiplexers MUX8A, MUX8B, MUX8C, and MUX8D may also be configured as dynamic multiplexers like shown in FIG. 26.

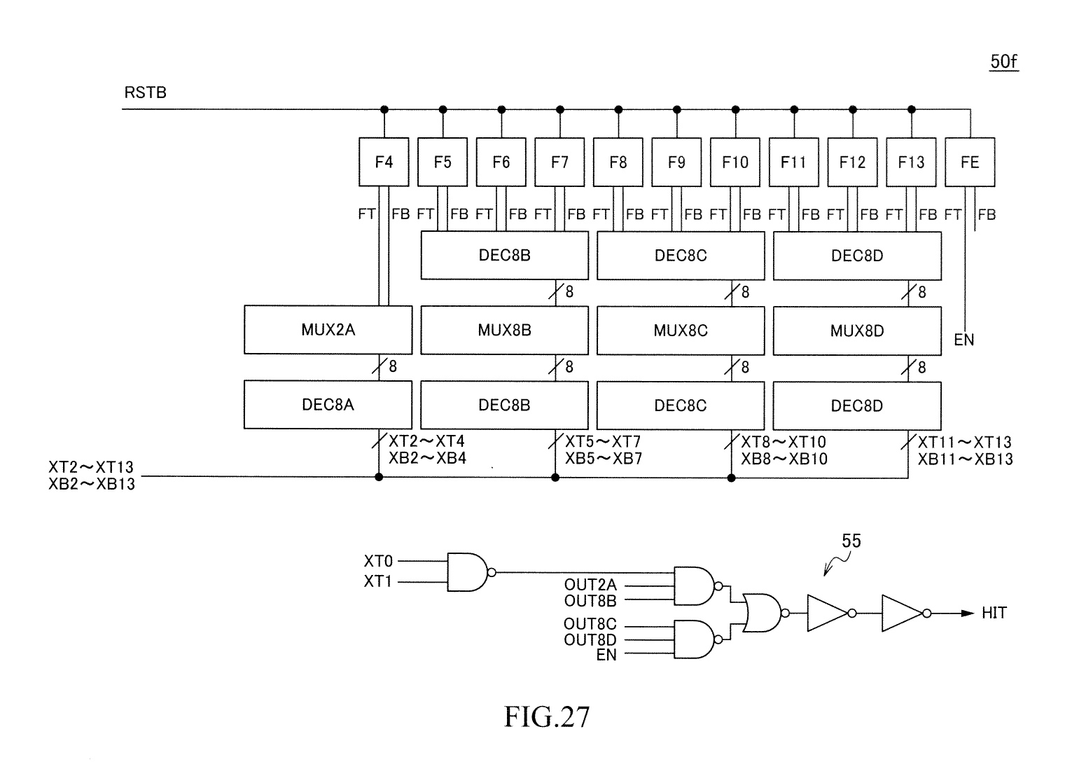

Turning to FIG. 27, there is a circuit diagram of a hit signal generation circuit 50f according to yet another modification.

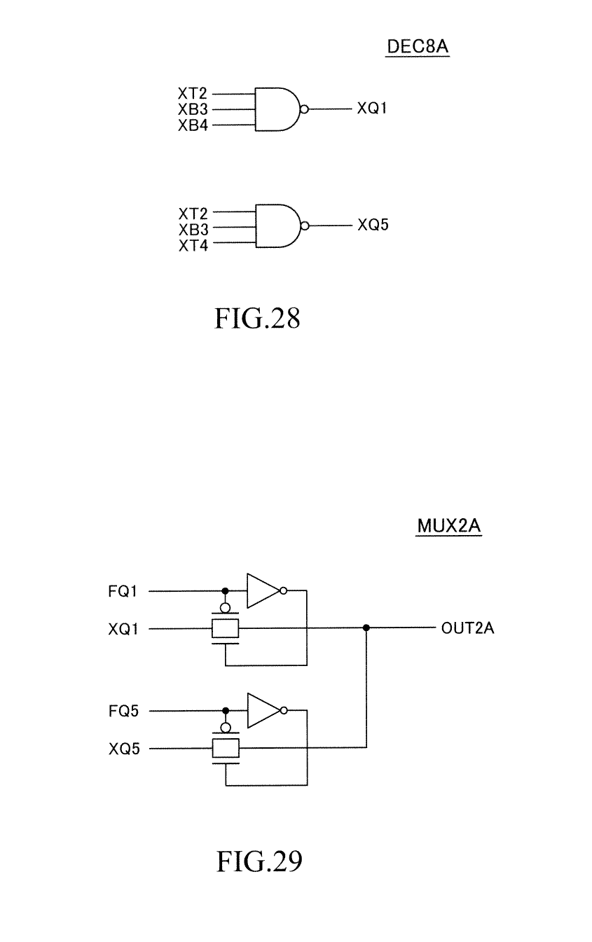

In the hit signal generation circuit 50f shown in FIG. 27, the lower four bits of the address signal are fixed. The fuse circuits F0 to F3 corresponding to the address bits X0 to X3 are therefore deleted. Decoders and multiplexers corresponding to the fuse circuits F0 to F3 are accordingly deleted or modified. To be more specific, the decoders DEC4A and the multiplexer MUX4A shown in FIG. 21 are deleted. The decoder DEC8A on the fuse circuit side is also deleted. The decoder DEC8A on the address bit side is replaced with the one shown in FIG. 28. The multiplexer MUX8A is replaced with a multiplexer MUX2A shown in FIG. 29.

The decoder DEC8A shown in FIG. 28 includes the NAND gate circuits for generating decoding signals XQ1 and XQ5, extracted from the decoder DEC8A shown in FIG. 23. The other NAND gate circuits are deleted. The multiplexer MUX2A shown in FIG. 29 includes the transfer gates 81 and 85 and controlling circuits thereof, extracted from the multiplexer MUX8A shown in FIG. 25. The other transfer gates and controlling circuits are deleted.

Such hit signal generation circuits 40f and 50f can be used to perform the same operation as described previously and provide the same effect.

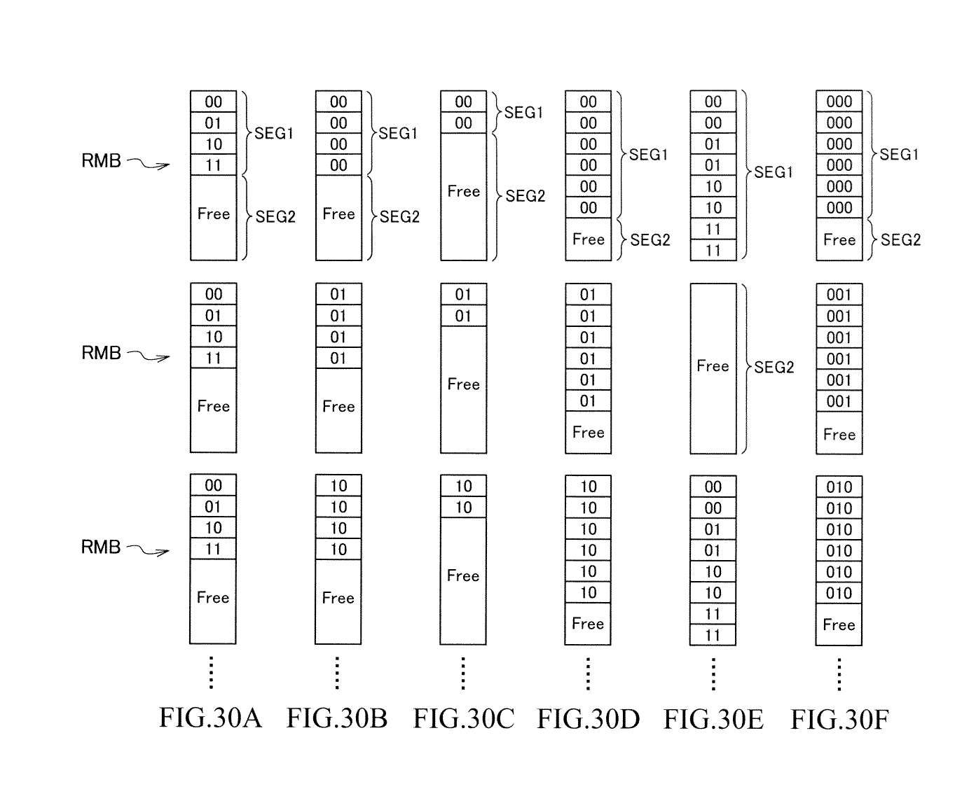

FIG. 30A shows an example of the same configuration as shown in FIG. 8. A memory block RMB includes both a redundant segment RSEG1 and a redundant segment RSEG2. The redundant segments RSEG1 in the respective memory blocks RMB use the same address allocation. The number of redundant segments RSEG1 is the same as that of redundant segments RSEG2. For example, each memory block RMB includes pairs of redundant word lines RWL whose address bits X0 and X1 have a fixed value of “00,” “01,” “10,” and “11,” respectively. Each memory block RMB also includes eight redundant word lines RWL whose address bits X1 and X0 are not fixed in value.

FIG. 30B shows an example where a memory block RMB includes both a redundant segment RSEG1 and a redundant segment RSEG2. The redundant segment RSEG1 assigned to a memory block RMB uses identical address allocation. The number of redundant segments RSEG1 is the same as that of redundant segments RSEG2. For example, each memory block RMB includes eight redundant word lines RWL whose address bits X0 and X1 are fixed to any one of “00,” “01,” “10,” and “11” in value, and eight redundant word lines RWL whose address bits X1 and X0 are not fixed in value. As seen above, according to the present invention, the address allocation in the redundant segments RSEG1 included in the respective memory blocks RMB need not always be the same.

FIG. 30C shows an example where the number of redundant word lines RWL constituting a redundant segment RSEG2 is greater than the number of redundant word lines RWL constituting a redundant segment RSEG1 in each memory block

RMB. For example, each memory block RMB includes four redundant word lines RWL whose address bits X0 and X1 are fixed to any one of “00,” “01,” “10,” and “11” in value, and twelve redundant word lines RWL whose address bits X1 and X0 are not fixed in value.

FIG. 30D shows an example where the number of redundant word lines RWL constituting a redundant segment RSEG2 is smaller than the number of redundant word lines RWL constituting a redundant segment RSEG1 in each memory block RMB. For example, each memory block RMB includes twelve redundant word lines RWL whose address bits X0 and X1 are fixed to any one of “00, ” “01, ” “10, ” and “11” in value, and four redundant word lines RWL whose address bits X1 and X0 are not fixed in value. As seen above, according to the present invention, the number of redundant word lines RWL constituting a redundant segment RSEG1 and the number of redundant word lines RWL constituting a redundant segment RSEG2 in each memory block RMB need not be the same.

FIG. 30E shows an example where all redundant word lines RWL included in each memory block RMB constitute either a redundant segment RSEG1 or a redundant segment RSEG2. For example, a memory block RMB includes sets of four redundant word lines RWL whose address bits X0 and X1 have a fixed value of “00, ” “01, ” “10,” and “11,” respectively, without redundant word lines RWL whose address bits X1 and X0 are not fixed in value. Another memory block RMB includes 16 redundant word lines RWL whose address bits X1 and X0 are not fixed in value, without redundant word lines RWL whose address bits X1 and X0 have a fixed value. As seen above, according to the present invention, each memory block RMB need not include both a redundant segment RSEG1 and a redundant segment RSEG2.

FIG. 30F shows an example where a memory block RMB includes both a redundant segment RSEG1 and a redundant segment RSEG2. The redundant segment RSEG1 assigned to a memory block RMB uses identical address allocation. The lower three bits of the address signal in the redundant segment RSEG1 are fixed. For example, each memory block RMB includes six redundant word lines RWL whose address bits X0 to X2 are fixed to any one of “000,” “001,” “010,” “011,” “100,” “101, “110,” and “111” in value, and two redundant word lines RWL whose address bits X2 to X0 are not fixed in value. As seen above, according to the present invention, the number of bits of an address signal to be fixed in a redundant segment RSEG1 is not limited.

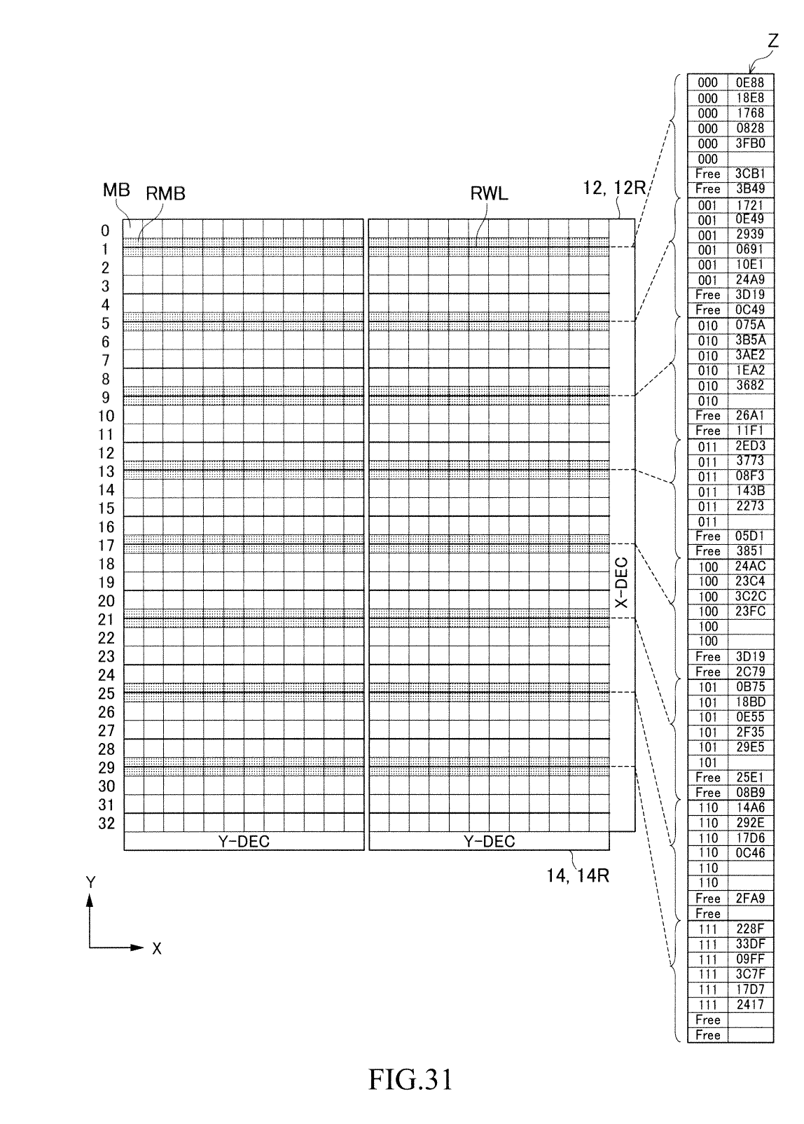

Turning to FIG. 31, there is a schematic diagram for explaining an example of replacement in a bank where memory blocks RMB have the structure shown in FIG. 30F.

In the example shown in FIG. 31, like the example shown in FIG. 3, 33 memory blocks divided in the Y direction constitute groups each including four blocks. The resulting eight groups each include a memory block RMB. Each memory block RMB includes six redundant word lines RWL that constitute a redundant segment RSEG1 and two redundant word lines RWL that constitute a redundant segment RSEG2. The six redundant word lines RWL constituting a redundant segment RSEG1 have fixed address bits which vary from one group to another. Consequently, each bank includes sets of six redundant word lines RWL whose address bits X0 to X2 have a fixed value of “000,” “001,” “010,” “011,” “100,” “101,” “110,” and “111,” respectively, and 16 redundant word lines RWL whose address bits X2 to X0 are not fixed in value.

In FIG. 31, the values Z in hexadecimal notation indicate the values of row addresses assigned to the redundant word lines RWL. In the example shown in FIG. 31, there are a lot of defective word lines whose address bits X0 to X2 have a value of “001” (in hexadecimal notation, the least significant digit is 1 or 9), and it is difficult to replace all such defective word lines with only the six redundant word lines RWL whose address bits X0 to X2 have a fixed value of “001.” However, the defective word lines that fail to be replaced with the six redundant word lines RWL with the address bits X0 to X2 of a fixed value “001” are replaced with other redundant word lines RWL that constitute redundant segments RSEG2. All the defective word lines are thereby replaced properly.

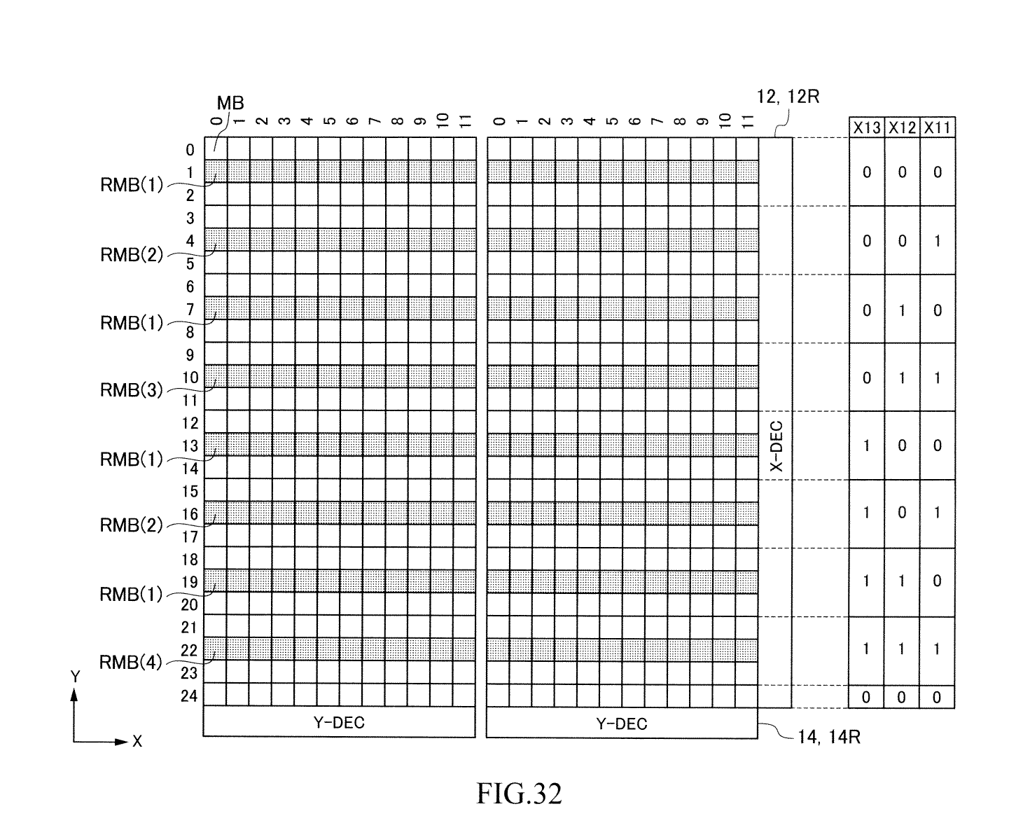

Turning to FIG. 32, there is a schematic diagram for explaining the structure of a memory bank according to another example.

In the example shown in FIG. 32, a single bank is divided into 24 memory blocks in the X direction and 25 memory blocks in the Y direction. In the present example, the 25 memory blocks divided in the Y direction constitute groups each including three blocks. Of the resulting eight groups, which group to select is specified by the address bits X13 to X11 of a row address. It should be noted that the group including the memory blocks MB0 to MB2 also includes the memory block MB24. Three memory blocks constituting each group include two normal memory blocks MB that include no redundant word line. The remaining one is a memory block RMB that includes redundant word lines. In FIG. 32, memory blocks RMB that include redundant word lines are shown hatched. As seen above, according to the present invention, the structure of a memory bank is not limited to the foregoing embodiment.

The memory blocks RMB included in the eight groups are classified into four types RMB (1) to RMB (4).

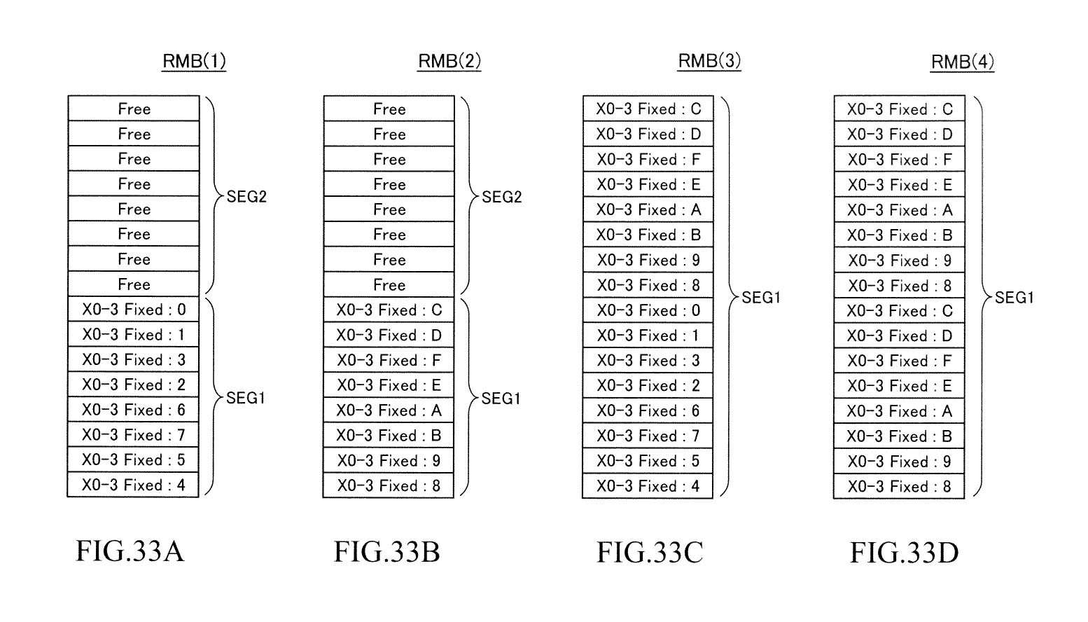

As shown in FIG. 33A, a first type of memory block RMB (1) includes both a redundant segment RSEG1 and a redundant segment RSEG2, each including eight redundant word lines RWL. The values of the address bits X0 to X3 of the eight redundant word lines RWL constituting the redundant segment RSEG1 are fixed to “0” to “7” in hexadecimal notation, respectively. Four memory blocks RMB (1) of first type are provided in the Y direction.

As shown in FIG. 33B, a second type of memory block RMB (2) includes both a redundant segment RSEG1 and a redundant segment RSEG2, each including eight redundant word lines RWL. The values of the address bits X0 to X3 of the eight redundant word lines RWL constituting the redundant segment RSEG1 are fixed to “8” to “F” in hexadecimal notation, respectively. Two memory blocks RMB (2) of second type are provided in the Y direction.

As shown in FIG. 33C, a third type of memory block RMB (3) includes only a redundant segment RSEG1, which includes 16 redundant word lines RWL. The values of the address bits X0 to X3 of the 16 redundant word lines RWL are fixed to “0” to “F” in hexadecimal notation, respectively. One memory block RMB (3) of third type is provided in the Y direction.

As shown in FIG. 33D, a fourth type of memory block RMB (4) includes only a redundant segment RSEG1, which includes 16 redundant word lines RWL. The 16 redundant word lines RWL include pairs of redundant word lines RWL whose address bits X0 to X3 have a fixed value of “8” to “F” in hexadecimal notation, respectively. One memory block RMB(4) of fourth type is provided in the Y direction.

Consequently, the 128 redundant word lines RWL include 80 redundant word lines RWL whose address bits X0 to X3 are fixed in value and 48 redundant word lines RWL whose address bits X0 to X3 are not fixed in value. The present invention may even employ such a configuration.

Up to this point, the preferred embodiment of the present invention has been described. However, the present invention is not limited to the foregoing embodiment. It will be understood that various modifications may be made without departing from the gist of the present invention, and such modifications are embraced within the scope of the present invention.

For example, the foregoing embodiment has dealt with the case where a lower address is fixed. However, the address to be fixed is not limited, and an intermediate address like X7 and X8 and an upper address like X12 and X13 may be fixed without problems.

The foregoing embodiment has dealt with the case of replacing defective word lines with redundant word lines. However, the present invention is not limited thereto. The present invention may be applied to replacement technologies in general for replacing defective select lines with redundant select lines. The present embodiment is thus also applicable when replacing defective bit lines with redundant bit lines, when replacing defecting blocks with redundant blocks, and/or when replacing defective memory cells with second volatile memory elements of second structure such as SRAM cells. Such memory cells and redundant memory cells may be nonvolatile memory elements.

The technical concept of the present invention may be applied to a semiconductor device that includes a volatile or nonvolatile memory. The forms of the circuits in the circuit blocks disclosed in the drawings and other circuits for generating control signals are not limited to the circuit forms disclosed in the embodiment.

The technical idea of the present application can be applied to various semiconductor devices. For example, the present invention can be applied to a general semiconductor device such as a CPU (Central Processing Unit), an MCU (Micro Control Unit), a DSP (Digital Signal Processor), an ASIC (Application Specific Integrated Circuit), and an ASSP (Application Specific Standard Circuit), each of which includes a memory function. An SOC (System on Chip), an MCP (Multi Chip Package), and a POP (Package on Package) and so on are pointed to as examples of types of semiconductor device to which the present invention is applied. The present invention can be applied to the semiconductor device that has these arbitrary product form and package form.

When the transistors are field effect transistors (FETs), various FETs are applicable, including MIS (Metal Insulator Semiconductor) and TFT (Thin Film Transistor) as well as MOS (Metal Oxide Semiconductor). The device may even include bipolar transistors.

In addition, an NMOS transistor (N-channel MOS transistor) is a representative example of a first conductive transistor, and a PMOS transistor (P-channel MOS transistor) is a representative example of a second conductive transistor.

Many combinations and selections of various constituent elements disclosed in this specification can be made within the scope of the appended claims of the present invention. That is, it is needles to mention that the present invention embraces the entire disclosure of this specification including the claims, as well as various changes and modifications which can be made by those skilled in the art based on the technical concept of the invention.

What is claimed is:

1. A semiconductor device comprising:
a plurality of segments exclusively selected based on a first address group configured by a plurality of address bits, each of the segments including a plurality of word lines exclusively selected based on a second address group configured by at least one address bit different from the address bits configuring the first address group;
a plurality of first redundant groups exclusively selected based on the second address group, each of the first redundant groups including a first redundant word line and a first fuse circuit that stores a respective first value, each of the first redundant word lines being selected when an associated one of the first redundant groups is selected based on the second address group and a value of the first address group is coincident with the first value stored in an associated one of the first fuse circuits; and
a second redundant group including a second redundant word line and a second fuse circuit that stores a second value, the second redundant word line being selected when a value of the first and second the address groups is coincident with the second value.

2. The device as claimed in claim 1, wherein
each of the first fuse circuits includes a plurality of fuse elements each storing a respective bit of the first value, and
each of the first redundant groups further includes a plurality of first comparison circuits each comparing a logical value of the bit stored in an associated one of fuse elements with an associated one of logical values of the first address group.

3. The device as claimed in claim 2, wherein each of the first redundant groups further includes a second comparison circuit that compares a logical value of the at least one address bit configuring the second address group with a predetermined logical value.

4. The device as claimed in claim 3, wherein each of the first comparison circuits and the second comparison circuit have substantially the same circuit configuration.

5. The device as claimed in claim 2, wherein each of the first redundant groups further includes a determination circuit that activates the first redundant word line when all the plurality of first comparison circuits detect a coincidence and the at least one address bit configuring the second address group has a predetermined logical value.

6. The device as claimed in claim 1, wherein
the second address group is configured by a plurality of address bits, and
two adjoining ones of the first redundant groups are selected by respective second address groups that differ from each other in one address bit.

7. A semiconductor device comprising:
a plurality of normal memory cells;
a plurality of first normal lines each coupled to corresponding one or ones of the normal memory cells;
a plurality of redundant memory cells; and
first and second redundant lines each coupled to corresponding one or ones of the redundant memory cells, the first redundant line being configured to replace selected one or ones of the normal lines and the second line being configure to replace any one of the selected one or ones of the normal lines and remaining one or ones of the normal lines.

8. The device as claimed in claim 7, wherein each of the normal lines serves as a normal word line and each of the first and second redundant lines serves as a redundant word line.

9. The device as claimed in claim 7, wherein the normal lines includes first and second normal lines, the first normal line being configured to be selected in response to a first selection signal, the second normal line being configured to be selected in response to a second selection signal, and the selected one or ones of the normal lines includes the first normal line and the remaining one or ones of the normal lines includes the second normal line.

10. The device as claimed in claim 7, further comprising a first fuse circuit for the first redundant line and a second fuse circuit for the second redundant line, the first fuse circuit being smaller in number of fuse units than the second fuse circuit.

11. The device as claimed in claim 10, wherein the first fuse circuit stores a first defective address in the fuse units thereof and the second fuse circuit stores a second defective address in the fuse units, the first defective address being smaller in number of bits than the second defective address.

12. The device as claimed in claim 11, wherein the second defective address is equal in bit length to a sum of the first defective address and one or more fixed bit information.

13. The device as claimed in claim 12, wherein the one or more fixed bit information includes a least significant bit.

14. A device comprising:
a normal memory cell array including a plurality of normal word lines and a plurality of normal memory cells each coupled to an associated one of the normal word lines, the normal word lines including a first group of normal word lines and a second group of normal word lines;
a redundant memory cell array including a plurality of redundant word lines and a plurality of redundant memory cells each coupled to an associated one of the redundant word lines, the redundant word lines including a plurality of first redundant word lines and a plurality of second redundant word lines; and
a redundant control circuit configured to restrict each of the first redundant word lines to replacing the first group of normal word lines and to assign each of the second redundant word lines for replacing both the first and second groups of normal word lines.

15. The device as claimed in claim 14, wherein a first one of the first group of normal word lines is replaced with one of the first redundant word lines, and a second one of the first group of normal word lines being replaced with a first one of the second redundant word line, and a first one of the second normal word lines being replaced with a second one of the second redundant word lines.
